(19) United States
(12) Patent Application Publication
(10) Pub. No.: US 2025/0334886 A1
(43) Pub. Date: Oct. 30, 2025

(54) METHOD FOR SIMULATING ILLUMINATION AND IMAGING PROPERTIES OF AN OPTICAL PRODUCTION SYSTEM WHEN AN OBJECT IS ILLUMINATED AND IMAGED BY MEANS OF AN OPTICAL MEASUREMENT SYSTEM

(71) Applicant: Carl Zeiss SMT GmbH, Oberkochen (DE)

(72) Inventors: Klaus Gwosch, Aalen (DE); Matthias Rösch, Aalen (DE)

(21) Appl. No.: 19/188,275

(22) Filed: Apr. 24, 2025

(30) Foreign Application Priority Data
Apr. 29, 2024 (DE) 102024204023.1

(51) Int. Cl. G03F 7/00

(52) U.S. Cl. CPC G03F 7/70504; G03F 7/70091; G03F 7/70666

(57) ABSTRACT

To simulate illumination and imaging properties of an optical production system when illuminating and imaging an object by use of an optical measurement system of a metrology system, a pupil stop of the optical measurement system is initially provided for the purpose of specifying at least one measurement illumination setting created by use of the pupil stop. Measurement aerial images Iₘₑₐₛ are recorded in an image plane of an imaging optics unit of the optical measurement system for different displacement positions of the object perpendicular to an object plane (xy) for the at least one measurement illumination setting. A complex mask transfer function M is reconstructed from the recorded measurement aerial images Iₘₑₐₛ. A 3-D aerial image Iₛᵢₘ of the optical production system is determined from the reconstructed mask transfer function M and a specified illumination setting σ_{target} of the optical production system as the result of the simulation method. The reconstruction includes the fact that the optical production system to be simulated comprises a production illumination setting BP_{y1}, BPy₂) to be simulated, with the latter varying in the object displacement direction (y). This yields an improved simulation method.

### CROSS-REFERENCE TO RELATED APPLICATION

The present application claims priority to German patent application DE 10 2024 204 023.1, filed on Apr. 29, 2024, the entire content of which is incorporated herein by reference.

### TECHNICAL FIELD

The invention relates to methods for simulating illumination and imaging properties of an optical production system when an object is illuminated and imaged, wherein the simulation is implemented by use of an optical measurement system of a metrology system. The invention also relates to a metrology system for performing such a method.

### BACKGROUND

Such a method and a metrology system to this end are known from DE 10 2019 208 552 A1, DE 10 2019 206 651 B4 and DE 10 2019 215 800 A1. A metrology system for measuring an aerial image of a lithography mask in three dimensions is known from WO 2016/012426 A1. DE 10 2013 219 524 A1 describes a device and a method for determining an imaging quality of an optical system, and an optical system. DE 10 2013 219 524 A1 describes a phase retrieval method for determining a wavefront on the basis of the imaging of a pinhole. The specialist article “A new system for a wafer lever CD metrology on photomasks,” proceedings of SPIE—The International Society for Optical Engineering, 2009, 7272, by Martin et al. has disclosed a metrology system for determining a wafer level critical dimension (CD). DE 10 2022 200 372 A1 discloses a method for simulating illumination and imaging properties of an optical production system. DE 10 2021 213 827 A1 discloses a method to optimize the shape of a pupil stop for simulating illumination and imaging properties of an optical production system. DE 10 2021 211 975 A1 discloses a method for simulating a target wavefront of an imaging optical production system. DE 10 2023 205 136 A1, disclosed after Apr. 29, 2024, discloses a method for simulating illumination and imaging properties of an optical production system. DE 10 2022 212 750 A1, disclosed after Apr. 29, 2024, discloses a method for three-dimensional determination of an aerial image of an object to be measured.

### SUMMARY

The problem addressed by the present invention is that of improving methods for simulating illumination and imaging properties of an optical production system when illuminating and imaging an object by use of an optical measurement system.

According to the invention, this problem is solved by a simulation method having the features specified in claim 1.

According to the invention, it was recognized that object displacement path-dependent aberrations of the optical production system in particular can be imaged more precisely when the simulation takes account of the fact that a production illumination setting to be simulated is present, with the latter varying in the object displacement direction, i.e. depending on the extent of object displacement, during production operation. In that case, the simulation is well adapted to the actual conditions of an object illumination realized by an optical production system in practice. Optical production systems having an object illumination realized by use of at least one facet mirror, in particular at least one MEMS mirror, for example by use of a honeycomb condenser or by use of the specular reflector, in particular may be simulated precisely in this way.

In addition to a variation in the object displacement direction of the production illumination setting to be simulated, which is taken into account by the simulation method, it is also possible to take account of a variation of the production illumination setting perpendicular to the project displacement direction, i.e. a field height dependence of the production illumination setting.

In the method according to claim 2, the simulation of the illumination and imaging properties of the optical production system utilizes a reconstruction that starts from a production illumination setting to be simulated, the latter varying in the object displacement direction during production operation. Such a reconstruction is adapted correspondingly well to the actual conditions of the object illumination realized by the optical production system in practice.

With the aid of the at least one pupil stop, a plurality of measurement illumination settings created by displacement of the pupil stop in the pupil plane may be provided in the simulation method and measurement aerial images may be recorded with these various measurement illumination settings, wherein these various measurement illumination settings may be specified in particular by displacing the pupil stop, but also by the use of different pupil stops.

The recording of measurement aerial images by use of the plurality of pupil stops, in particular the recording of measurement aerial images in a plurality of measurement positions of a pupil stop, which was selected in advance for the best possible simulation of the illumination setting of the optical production system, provides the possibility of improving the accuracy of the simulation method overall and in particular provides the option of reducing illumination angle-dependent artefacts, in particular, in the reconstructed complex mask transfer function, i.e. in the transfer function of the imaged object. It is then possible to correctly take account of 3-D mask effects. The simulation method can be considered when examining lithography masks, especially when examining masks used for EUV lithography.

The provided pupil stop is an illumination optics unit stop, with the pupil stop being arrangeable in an illumination pupil region regularly present in an illumination optics unit pupil plane.

In addition to that, the optical measurement system may comprise a further stop in a measurement system imaging optics unit for imaging the object. This image-side, further stop can be an aperture stop. A shadowing effect on such an aperture stop may also be taken into account in the simulation method.

A part of the simulation method may be, in particular, a provision of information regarding the respective image-side, further stop utilized, in particular a provision of contour information for this image-side, further stop and also for example information about a thickness of a stop body of the stop.

Simulation variants according to claim 3 lead to imaging of the optical production system accordingly adapted to practice. Part of the simulation may be the reconstruction that was explained above, in particular in the context of claim 2.

According to the invention, the problem specified at the outset is also solved by a simulation method having the features specified in claim 4.

According to the invention, it was further recognized that the simulation method allows, without undesirable loss of precision, the use of a measurement illumination setting with a pupil filling degree or pupil fill ratio that is greater than that of the production illumination setting to be simulated. This increases a measurement light throughput, especially when recording the measurement aerial images, accelerating the simulation method.

The pupil filling degree is defined as the area of an illuminated portion of a pupil in relation to the overall area of the pupil.

The production illumination setting regularly has a small pupil filling degree since this allows an object illumination with exactly defined illumination angles. This goal of a small pupil filling degree is explained in U.S. Pat. No. 10,018,917, for example.

In comparison, the measurement illumination setting may have a larger measurement pupil filling degree. An illuminated pupil area of the measurement illumination setting may be 5%, may be 10%, may be 15%, may be 20%, may be 25%, may be 30%, may be 35%, may be 40%, may be 45%, may be 50%, may be 55%, may be 60%, may be 65%, may be 70%, may be 75%, may be 80%, may be 85%, may be 90%, may be 95%, may be 100% greater than the illuminated pupil area of the production illumination setting or may be greater still.

An illuminated pupil area of the measurement illumination setting according to claim 5 leads to an advantageous high measurement light throughput, in particular in the aerial image recording step of the simulation method. The illuminated pupil area of the measurement illumination setting may be at least 1.5 times, at least 1.75 times, at least 2 times, at least 2.5 times the illuminated pupil area of the production illumination setting or, relative thereto, may be greater still. The illuminated pupil area of the measurement illumination setting is regularly less than 10 times the illuminated pupil area of the production illumination setting. Depending on the boundary conditions of the simulation method, the illuminated pupil area of the measurement illumination setting may also be just as large as the illuminated pupil area of the production illumination setting to be simulated.

The aforementioned relationships between the pupil areas relate to pupil areas of the measurement illumination setting on the one hand and of the production illumination setting on the other hand, said pupil areas having been normalized in the same way in both cases.

A correction according claim 6, which may include the respective reconstructed spectra of an illumination setting, takes account of an influence on the illumination setting by the optical production system imaging optics unit on the one hand and a corresponding influence of the metrology system measurement optics unit on the other hand. The same reconstructed spectra may be included in both correction terms. This can be used to eliminate errors that occur during the reconstruction of the spectra. The use of corresponding correction terms in the mask transfer function reconstruction is known from DE 10 2019 208 552 A1 (corresponding to U.S. publication 2022/0101569) and DE 10 2019 206 651 B4 (corresponding to PCT publication WO2020225411), the contents of the above applications/publications are incorporated by reference.

The use of a pupil stop with a stop shape optimized according to claim 7 already yields a good simulation of the optical production system illumination properties at the starting point. In that case, the simulation method can be used to obtain highest possible accuracies of the simulation.

A separate optimization for different displacement positions according to claim 8 gives rise to a further option for improving the accuracy of the simulation method. The use of a compensation rule, in particular a weighted compensation rule, allows the simulation accuracy to be increased when simulating in the region of object displacement positions for which no measurement pupil stop was provided.

The advantages of a metrology system according to claims 9 to 12 correspond to those that have already been explained above with reference to the method claims.

A displacement drive for displacing the pupil stop according to claim 10 has proven its worth for the reproducible specification of pupil stop measurement positions. This applies correspondingly to an object holder, which is displaceable perpendicular to the object plane, and to a displacement drive for displacing an imaging pupil stop according to claim 11.

A selection apparatus having a stop storage unit according to claim 12 advantageously enables the pupil stop selection step of the simulation method. In particular, the selection can be made with the aid of a robotic actuation system which takes the respective selected pupil stop from the stop storage unit and moves it to its use location in the pupil plane. The selection apparatus moreover ensures a substitution of a last-used pupil stop for a newly selected pupil stop. In particular, the last-used pupil stop can be transferred from the use location back to the stop storage unit by use of the robotic actuation system in that case.

An aperture of the stop, i.e. of the illumination pupil stop and/or the imaging pupil stop, may also be variably specifiable, for example in the style of an iris diaphragm.

The metrology system may comprise a light source for the illumination light. A light source of this type may be configured as an EUV light source.

An EUV wavelength of the light source may range between 5 nm and 30 nm. A light source in the DUV wavelength range, for example of the order of 193 nm, is also possible.

Within the scope of the simulation method, it is possible to select precisely one pupil stop from the plurality of pupil stops provided, which may differ in terms of their stop boundary shape and/or in terms of their stop boundary orientation. Alternatively, it is possible to select and use a plurality of different pupil stops for the purpose of specifying different measurement positions. The pupil stops provided may specify at least one of the following illumination settings in particular: Quadrupole, C-quad, dipole, annular, conventional. A person skilled in the art finds examples for such settings in, inter alia, WO 2012/028 303 A1, the content of which is incorporated by reference. First of all, there may be an initial determination of a best focal plane (defocus value zₘ=0) within the preparation of the imaging method. z-increments when determining the 3-D aerial image in the last step of the simulation method, i.e. when determining the aerial image from the reconstructed mask transfer function and the optical production system illumination setting, may differ from defocus values that may at first be specified in the simulation method. Pixel sizes of the recorded measurement aerial images may be sampled for the purpose of an adaptation to the desired pixel resolution.

The target pupil stop, which may be specified, and the target stop boundary shape thereof may relate to a plurality of, or else a multiplicity of, individual illumination or pupil spots, i.e. a plurality of stop apertures for example arranged in a grid-like manner. Such illumination or pupil spots may yield an illumination setting used within the scope of the production illumination, the said illumination setting for example being able to be set by way of an illumination optics unit having at least one MEMS-based facet mirror, in particular in the style of a specular reflector, or by way of an illumination optics unit having a field facet mirror and a pupil facet mirror.

In principle, a specular reflector is known from US 2006/0132747 A1, EP 1 614 008 B1, U.S. Pat. Nos. 9,915,875 B2 and 6,573,978. For example, a honeycomb condenser is known from U.S. Pat. No. 10,488,567 B2 or U.S. Pat. No. 11,500,294 B2. The contents of US 2006/0132747, EP 1 614 008, U.S. Pat. Nos. 9,915,875, 10,488,567, and 11,500,294 are incorporated by reference.

### BRIEF DESCRIPTION OF THE DRAWINGS

Exemplary embodiments of the invention are explained in greater detail below on the basis of the drawing, in which:

FIG. 1 very schematically shows a side view of a metrology system for simulating illumination and imaging properties of an optical production system when illuminating and imaging an object, the metrology system comprising an illumination optics unit and an imaging optics unit, both of which are depicted very schematically in each case;

FIGS. 2A to 9D show different variants of a metrology system pupil stop which is arrangeable in the region of an illumination pupil of the illumination optics unit;

FIG. 10 shows an example of an illumination setting of the optical production system to be simulated, represented by an intensity distribution over an illumination pupil in an optical production system pupil plane;

FIGS. 11A to 11I show an embodiment of a sequence of measurement positions of one of the pupil stops according to FIGS. 2 to 9 using the example of the pupil stop according to FIG. 2B, with the measurement position sequence being used within a method, performed by the metrology system, for simulating the illumination and imaging properties of the optical production system when illuminating and imaging the object using the metrology system optical measurement system;

FIGS. 12A to 12F show a further embodiment of a sequence of measurement positions of the metrology system pupil stop in a representation similar to that of FIGS. 11A to 11I;

FIGS. 13A to 13I show a further embodiment of a sequence of measurement positions of the metrology system pupil stop in a representation similar to that of FIGS. 11A to 11I;

FIGS. 14A to 14C show a further embodiment of a sequence of measurement positions of the metrology system pupil stop in a representation similar to that of FIGS. 11A to 11I;

FIG. 15 shows, in a pupil coordinate representation, a comparison between a target illumination setting of the production system, which is intended to be approximated by a metrology system pupil stop, and a pupil stop candidate using the example of a metrology system pupil stop comparable to the pupil stop according to FIG. 7A, with this comparison being part of an algorithm for selecting at least one metrology system pupil stop from the provided plurality of pupil stops;

FIG. 16 shows a plan view of a binary, periodic test structure which is arranged at XVI in the metrology system according to FIG. 1;

FIG. 17 shows, likewise in a plan view according to FIG. 16, a field distribution of an electromagnetic field of the illumination light in the illumination light beam path at XVII in FIG. 1, following an irradiation of the test structure;

FIG. 18 shows, once again in a plan view according to FIG. 16, a diffraction spectrum of the test structure in the illumination light beam path at XVIII in FIG. 1;

FIG. 19 shows, in a representation similar to FIG. 18, the diffraction spectrum that has been curtailed at the edge on account of an aperture stop of the metrology system, said aperture stop being at XIX in FIG. 1;

FIG. 20 shows, in a representation similar to FIG. 19, the diffraction spectrum including wavefront influences, indicated as height contours, by the metrology system imaging optics unit as measured spectrum in the region of an exit pupil of the imaging optics unit at XX in FIG. 1;

FIG. 21 shows, in a plan view similar to FIG. 17, a complex field distribution of the illumination light upon irradiation of a spatially resolving metrology system detection device in the imaging light beam path at XXI in FIG. 1;

FIG. 22 shows, in a representation similar to FIG. 21, an illumination light intensity, as measured by the detection device, at the location of the detection device at XXII in FIG. 1;

FIG. 23 shows, schematically and in exaggerated fashion, a field variation of an illumination setting of the optical production system to be simulated, additionally in a manner dependent on a chief ray illumination direction and dependent on a field coordinate perpendicular to an object displacement direction of the production system;

FIG. 23A shows, in perspective, an object field which is rectangular in this case and has a chief ray incident on an object field point, for the purpose of defining two chief ray angles of incidence;

FIG. 24 shows an interrupted detail of a fabrication metal sheet having a pupil stop which may be used in the optical measurement system of the metrology system when simulating the illumination and imaging properties of the optical production system, with a stop shape of the pupil stop being optimized by use of a method for optimizing a match quality between the illumination and imaging properties of the optical production system and of the optical measurement system, with additional alignment marker openings being depicted;

FIG. 25 shows the target stop shape for two different chief ray illumination directions that arises within the scope of the optimization method for the pupil stop according to FIG. 24;

FIG. 26 shows an exit pupil stop of a projection optics unit of the optical production system, with an effective inner stop boundary and an effective outer stop boundary being elucidated for two different field locations or field points;

FIG. 27 shows, in a representation similar to FIG. 26, an exit pupil stop of an imaging optics unit of the optical measurement system, with effective stop boundaries for two different field locations, which correspond to the field locations in FIG. 26, likewise being depicted;

FIGS. 28A to 28D show different variants or measurement position sequences of metrology system pupil stops in the style of FIGS. 11 to 14 in a representation similar to FIGS. 26 and 27, depicting firstly an ideal stop shape and secondly an actually effectively acting stop boundary shape which depends on the respective illumination chief ray angle utilized;

FIG. 29 shows a flowchart of a method for optimizing a stop shape of a pupil stop in the metrology system for simulating illumination and imaging properties of the optical production system when the object is illuminated and imaged by use of the optical measurement system of the metrology system;

FIG. 30 schematically shows an instantaneous overlap between an illumination pupil and a pupil of the imaging optics unit of an optical system having an illumination optics unit and an imaging optics unit, for elucidating a method for optimizing a match quality between the illumination and imaging properties of the optical production system and of the optical measurement system;

FIG. 30A shows an illumination pupil (on the left) and a projection optics unit exit pupil (on the right) of an optical production system which is simulated in respect of its optical properties by way of the metrology system;

FIG. 30B shows a sigma pupil stop shape (on the left) and an NA aperture stop shape (on the right) of the optical measurement system of the metrology system for simulating the pupil configurations according to FIG. 30A which were found in the context of a stop shape optimization method;

FIG. 31 schematically shows a representation of the object field for elucidating an averaging of aerial images if no physical stop is available at a measurement point;

FIGS. 32A to 32V show examples of standard illumination settings of the optical production system to be simulated, once again represented in each case by an intensity distribution over an illumination pupil in an optical production system pupil plane;

FIG. 33 shows a comparison of the production illumination setting corresponding to FIG. 32D and of the measurement illumination setting corresponding to FIG. 5C; and

FIG. 34 shows, in a representation similar to FIG. 23 and once again in schematic and exaggerated fashion, a field variation of an illumination setting of the optical production system to be simulated, the field variation depending on a field coordinate parallel to the object displacement direction of the production system.

### DETAILED DESCRIPTION

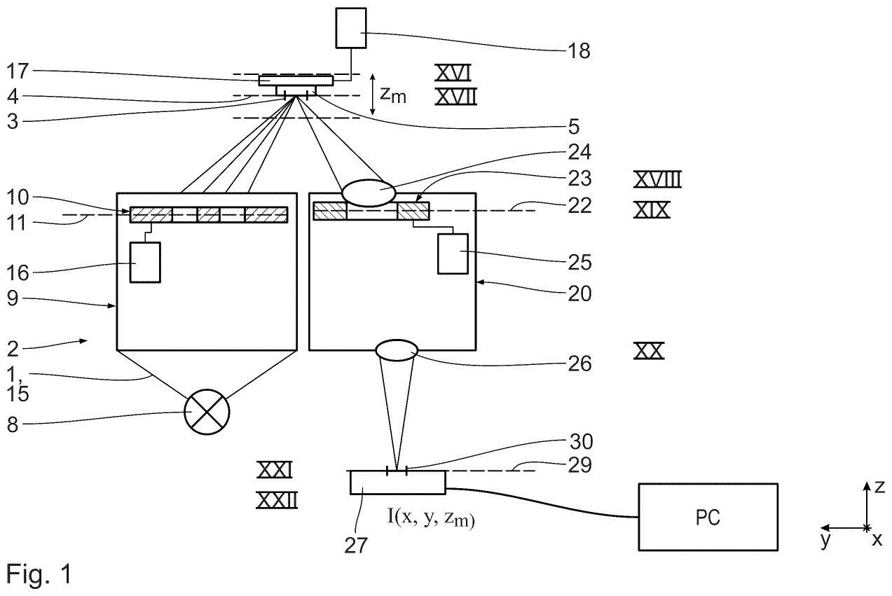

In order to facilitate the representation of positional relationships, a Cartesian xyz-coordinate system will be used hereinafter. In FIG. 1, the x-axis extends perpendicularly to the plane of the drawing into the latter. The y-axis extends toward the left in FIG. 1. The z-axis extends vertically upwards in FIG. 1.

In a view that corresponds to a meridional section, FIG. 1 shows a beam path of EUV illumination light or imaging light 1 in a metrology system 2 for simulation of illumination and imaging properties of an optical production system when an object is illuminated and imaged by use of an optical measurement system of the metrology system 2. Examples of an optical production system to be simulated are disclosed in DE 10 2023 209 707 A1 and in U.S. Pat. No. 9,977,335 B2, the contents of the above patent application and patent are incorporated by reference. A test structure 5 arranged in an object field 3 in an object plane 4 is imaged.

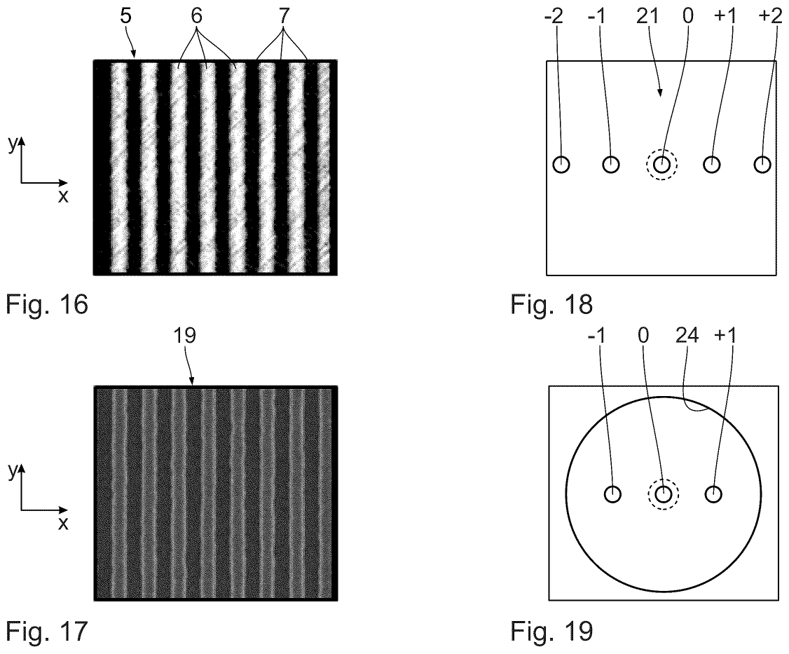

An example of the test structure 5 is depicted in a plan view in FIG. 16. The test structure 5 is periodic in one dimension, specifically along the y-coordinate for example. The test structure 5 is embodied as a binary test structure with absorber lines 6 and in each case alternating multilayer lines 7 which reflect the illumination light 1. The lines 6, 7 are vertical structures, which extend e.g. in the y-direction.

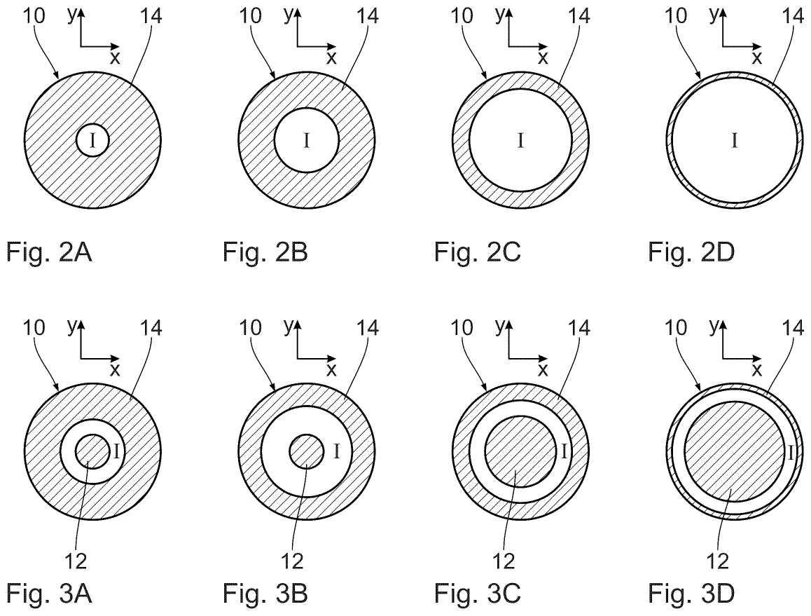

The metrology system 2 is used to analyze a three-dimensional (3-D) aerial image (aerial image metrology system). One application is found in the simulation of an aerial image of a lithography mask, in the way that the aerial image would also appear in an optical production system of a producing projection exposure apparatus, for example in a scanner. To this end, an imaging quality of the metrology system 2 itself, in particular, can be measured and optionally adjusted. Consequently, the analysis of the aerial image can serve to determine the imaging quality of a projection optics unit of the metrology system 2, or else to determine the imaging quality of, in particular, projection optics units within a projection exposure apparatus. Metrology systems are known from DE 10 2019 208 552 A1, from WO 2016/012 426 A1, from US 2013/0063716 A1 (cf. FIG. 3 therein), from DE 102 20 815 A1 (cf. FIG. 9 therein), from DE 102 20 816 A1 (cf. FIG. 2 therein) and from US 2013/0083321 A1.

The illumination light 1 is reflected and diffracted off the test structure 5. A plane of incidence of the illumination light 1 is parallel to the yz-plane in the case of the central, initial illumination.

The EUV illumination light 1 is created by an EUV light source 8. The light source 8 can be a laser plasma source (LPP; laser produced plasma) or a discharge source (DPP; discharge produced plasma). In principle, a synchrotron-based light source can also be used, e.g. a free electron laser (FEL). A used wavelength of the EUV light source can range between 5 nm and 30 nm. In principle, in one variant of the metrology system 2, a light source for another used light wavelength can also be used instead of the light source 8, for example a light source for a used wavelength of 193 nm.

An illumination optics unit 9 of the metrology system 2 is arranged between the light source 8 and the test structure 5. The illumination optics unit 9 may include in a beam path of the EUV illumination light 1 after a collector mirror to collect the light generated by the light source 8 one or more mirrors to guide the illumination light 1 to the object field 3. Such mirrors may carry a high reflection coating to enhance the reflectivity for the illumination light 1. The illumination optics unit 9 serves for the illumination of the test structure 5 to be examined, with a defined illumination intensity distribution over the object field 3 and at the same time with a defined illumination angle distribution with which the field points of the object field 3 are illuminated. Such an illumination angle distribution is also referred to as illumination setting.

The respective illumination angle distribution of the illumination light 1 is specified by way of a pupil stop 10, which is arranged in an illumination optics unit pupil plane 11. The pupil stop 10 is also referred to as sigma stop.

FIGS. 2A to 9D show possible embodiments of such pupil stops 10, which can be used as alternatives in the illumination optics unit 9 of the metrology system 2 for the purpose of specifying the illumination setting. Components and functions corresponding to those already explained in relation to a preceding figure are not discussed again in detail in a subsequent figure, and, where applicable, are denoted there using the same reference signs.

FIG. 2A shows a pupil stop 10 with a single central passage pole I. A radius of this passage pole I is approximately a quarter of a diameter of a peripheral aperture stop portion 14 of the pupil stop 10. A central illumination angle for the object field 3 with relatively small angular variation is selected by way of the pupil stop 10 according to FIG. 2A. In FIGS. 2A to 3D, the shaded regions represent opaque regions that block the EUV illumination light 1. For example, the pupil stop 10 can be made of metal, in particular can be made of steel or of aluminium. In particular, the pupil stop 10 may be manufactured from a material with high thermal conductivity.

Further variants of pupil stops 10 with a central passage pole I of increasingly larger radius are shown in FIGS. 2B to 2D. There is an according increase in object field illumination angle variation when the pupil stops 10 according to FIGS. 2B to 2D are used. The pupil stop 10 according to FIG. 2D yields a conventional illumination setting, in which light can pass through the illumination optics unit pupil plane 11 of the metrology system 2 practically unimpeded.

FIG. 3A shows a variant of a pupil stop 10 with a ring-shaped passage portion I, which is arranged around a round, central obscuration stop portion 12. An internal diameter of the ring-shaped passage pole I for the pupil stop according to FIG. 3A is approximately the same size as an external diameter of the illumination pole I of the pupil stop 10 according to FIG. 2A. An external diameter of the ring-shaped passage pole I of the pupil stop 10 according to FIG. 3A is approximately twice the size.

FIG. 3B shows a variant of the pupil stop 10 in which, in comparison with FIG. 3A, an external diameter of the ring-shaped passage pole I is approximately 2.5-times as large as the internal diameter. The central obscuration stop portion 12 for the pupil stop 10 according to FIG. 3B is the same size as the one according to FIG. 3A.

FIG. 3C shows a variant of the pupil stop 10 with a ring-shaped passage pole I with an internal diameter approximately doubled in size in comparison with that of FIGS. 3A and 3B, and with an external diameter that is only slightly larger than that of the passage pole I according to FIG. 3B. This results in a correspondingly large central obscuration stop portion 12.

FIG. 3D shows an illumination pupil 10 with a ring-shaped illumination pole I, the ring-shaped thickness of which approximately corresponds to that of the embodiment according to FIG. 3C, with a diameter of the ring-shaped illumination pole I being maximized in the embodiment according to FIG. 3D, and so only a relatively thin aperture stop portion 14 remains on the side of the edge. This results in a correspondingly large central obscuration stop portion 12, which is larger in the embodiment according to FIG. 3D than in the embodiment according to FIG. 3C.

Corresponding annular illumination settings can be realized using the embodiments of the pupil stops 10 according to FIGS. 3A to 3D.

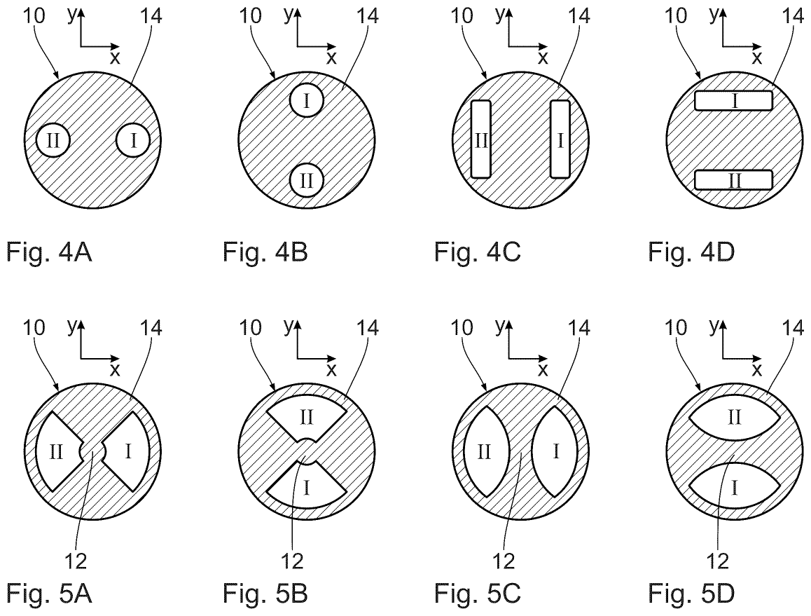

FIG. 4A shows a dipole pupil stop 10 embodied as an x-dipole. The two poles I and II are round in each case and have a diameter which in each case corresponds to the diameter of the central passage pole I of the pupil stop 10 according to FIG. 2A.

FIG. 4B shows a dipole pupil stop 10 embodied as a y-dipole with poles I, II which correspond to those of the embodiment according to FIG. 4A in terms of their shape and size. The pupil stop 10 according to FIG. 4B can be created by rotating the pupil stop 10 according to FIG. 4A through 90° about an axis parallel to the z-axis.

FIG. 4C shows a further embodiment of an x-dipole pupil stop 10 with passage poles I, II which have a rectangular embodiment with an x/y-aspect ratio of approximately 1/4.

FIG. 4D shows a y-dipole pupil stop 10 corresponding to the x-dipole pupil stop 10 according to FIG. 4C.

FIG. 5A in turn shows an x-dipole pupil stop 10, with each of the open poles I, II having a circumferential extent of approximately 90°. Once again, a central obscuration stop portion 12 is located between the two passage poles I, II.

FIG. 5B in turn shows a y-dipole pupil stop 10 corresponding to the x-dipole pupil stop 10 according to FIG. 5A.

FIG. 5C shows an x-dipole pupil stop 10, in which the individual poles I, II are embodied as leaflets, i.e. each have a biconvex shape.

FIG. 5D shows a y-dipole pupil stop 10 corresponding to the x-dipole pupil stop 10 according to FIG. 5C.

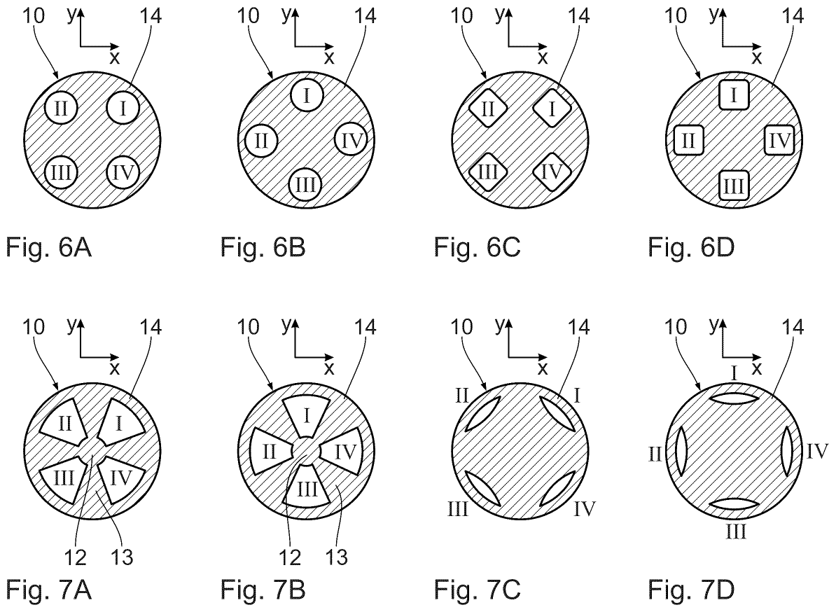

FIG. 6A shows an embodiment of a quadrupole pupil stop 10 with four round passage poles I, II, III and IV arranged in the quadrants. A diameter of these passage poles I to IV corresponds to that of the passage pole I of the pupil stop 10 according to FIG. 2A.

FIG. 6B shows a variant of the pupil stop 10 which can be created from the variant according to FIG. 6A by way of a twist through 45° about an axis parallel to the z-axis, in which variant the four poles I to IV are thus arranged as a superposition of an x-dipole pupil stop and a y-dipole pupil stop according to FIGS. 4A and 4B.

FIG. 6C shows a variant of a corresponding quadrupole pupil stop 10 with square passage poles I to IV, once again arranged in the quadrants.

FIG. 6D in turn shows the arrangement corresponding to FIG. 6B, albeit with square passage poles I to IV, rotated through 45° in comparison with FIG. 6C.

FIG. 7A shows a variant of a quadrupole pupil stop 10 with sector-type poles I to IV arranged in the quadrants, each having a circumferential extent of approximately 45°. Connecting pieces 13 between adjacent passage poles I to IV of the pupil stop 10 according to FIG. 7A likewise have a circumferential extent of approximately 45° in each case. Once again, a central obscuration stop portion 12 is located in the center of the pupil stop 10 according to FIG. 7A.

FIG. 7B shows a quadrupole pupil stop 10 which corresponds to the embodiment according to FIG. 7A and which can be created by rotation through 45° about an axis parallel to the x-axis.

FIG. 7C shows a variant of a quadrupole pupil stop 10 with passage poles I to IV in the form of leaflets which, in the circumferential direction around a stop center, are arranged in the vicinity of the aperture stop portion 14 on the side of the edge.

FIG. 7D shows a variant of the quadrupole pupil stop which corresponds to that according to FIG. 7C and which can be created by rotation through 45° about an axis parallel to the z-axis.

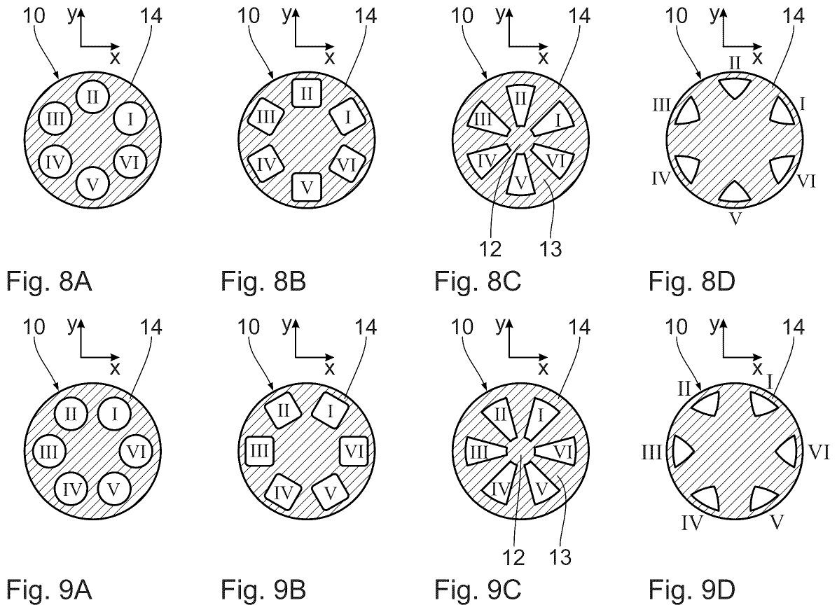

FIG. 8A shows a hexapole pupil stop 10 with six round passage poles I to VI which are arranged about the stop center so as to be uniformly distributed in the circumferential direction. A diameter of the poles I to VI corresponds to that of the passage pole I of the pupil stop 10 according to FIG. 2A. A distance between two adjacent poles I to VI is approximately one third of a pole diameter.

Measured from the x-coordinate of the pupil stop 10 of FIG. 8A, the six poles are arranged at the positions of 30°, 90°, 150°, 210°, 270° and 330°.

FIG. 8B shows a variant of a hexapole pupil stop 10 which corresponds to that according to FIG. 8A, apart from the edge contour of the passage poles I to VI which is square in the embodiment according to FIG. 8B.

FIG. 8C shows a variant of a hexapole pupil stop 10 which corresponds to that according to FIG. 8A, apart from the edge contour of the passage poles I to VI which is sector-type in the embodiment according to FIG. 8C. A circumferential extent of the sector-type passage poles I to VI is approximately 30° and corresponds to a circumferential extent of the connecting pieces between in each case adjacent passage poles I to VI.

FIG. 8D shows a variant of a hexapole pupil stop 10 which corresponds to that according to FIG. 8A, apart from the edge contour of the passage poles I to VI which is approximately triangular near the aperture stop portion 14 on the side of the edge in the embodiment according to FIG. 8D.

FIG. 9A shows a variant of a hexapole pupil stop 10 which can be created from the variant according to FIG. 8A by way of a rotation through 30° about an axis parallel to the z-axis.

FIG. 9B shows a variant of a hexapole pupil stop 10 which can be created from the variant according to FIG. 8B by way of a rotation through 30° about an axis parallel to the z-axis.

FIG. 9C shows a variant of a hexapole pupil stop 10 which can be created from the variant according to FIG. 8C by way of a rotation through 30° about an axis parallel to the z-axis.

FIG. 9D shows a variant of a hexapole pupil stop 10 which can be created from the variant according to FIG. 8D by way of a rotation through 30° about an axis parallel to the z-axis.

The pupil stop 10 of the illumination optics unit 9 is embodied as a stop which is displaceable in driven fashion and which is arranged in front of the object plane 4 in an illumination light beam path 15 of the illumination light 1. A drive unit used for the driven displacement of the pupil stop 10 is depicted at 16 in FIG. 1. By use of the drive unit 16, also referred to as a displacement drive, the pupil stop can be displaced along the x-coordinate and/or along the y-coordinate. A fine setting along the z-coordinate for the purpose of adjusting a match of an arrangement plane of the pupil stop 10 relative to the illumination optics unit pupil plane 11 is also possible by way of the drive unit 16. Moreover, the drive unit 16 can be designed such that a tilt of the stop about at least one tilt axis parallel to the x-axis and/or parallel to the y-axis is possible. Additionally, a diameter of the obscuration stop portion 12 and/or aperture stop portion 14 and/or a size of the poles I; I, II; I, II, III, IV; I, II, III, IV, V, VI of the respective embodiment of the pupil stop 10 may be specifiable in settable and, in particular, driven fashion.

With the aid of the displacement drive 16, it is possible to displace the selected pupil stop 10 along the pupil coordinates kₓ and k_{y} in the pupil plane 11.

The displacement drive 16 may also include a stop interchange unit, by means of which a specific pupil stop 10 is replaced with another, specified pupil stop 10. To this end, the stop interchange unit may take the respective selected pupil stop from a stop storage unit and return the replaced stop to this stop storage unit.

The test structure 5 is held by an object holder 17 of the metrology system 2. The object holder 17 cooperates with an object displacement drive 18 for displacing the test structure 5, in particular along the z-coordinate.

Following reflection at the test structure 5, the electromagnetic field of the illumination light 1 has a distribution 19 which is depicted in FIG. 17 in a plan view corresponding to that of FIG. 16. In the field distribution 19, amplitudes and phase values correspond to the absorber lines 6 and the multilayer lines 7 of the test structure 5.

The illumination light 1 reflected off the test structure 5 enters an imaging optics unit or projection optics unit 20 of the metrology system 2. The imaging optics unit 20 comprises a plurality of mirrors for guiding the illumination light 1. Depending on the respective embodiment, the imaging optics unit 20 may comprise two to eight mirrors. These mirrors may comprise a high reflective coating for the illumination light 1.

A diffraction spectrum 21 arises in a pupil plane of the projection optics unit 20 on account of the periodicity of the test structure 5 (cf. FIG. 18).

In the diffraction spectrum 21, the 0th order of diffraction of the test structure 5 is present centrally. In addition, FIG. 18 also represents the +/−1st order of diffraction and the +/−2nd order of diffraction of the diffraction spectrum 21.

The orders of diffraction of the diffraction spectrum 21 depicted in FIG. 18 appear in this form in a pupil plane of the optical system of the metrology system 2, for example in an entrance pupil plane 22 of the projection optics unit 20. An aperture stop 23 of the projection optics unit 20 which bounds an entrance pupil 24 of the projection optics unit 20 on the edge side, i.e. to the outside for the purpose of specifying the numerical aperture and optionally to the inside for the purpose of specifying an inner obscuration, is arranged in this entrance pupil plane 22. The aperture stop 23 is also referred to as the imaging pupil stop of metrology system 2. FIG. 27 shows an example of such an aperture stop 23 of the metrology system 2.

The imaging pupil stop 23 is operatively connected to a displacement drive 25, the function of which corresponds to that of the displacement drive 16 for the sigma stop 10. The displacement drive 25 includes a drive unit which may include an electromechanic actor and/or a piezo actor and/or a linear actor.

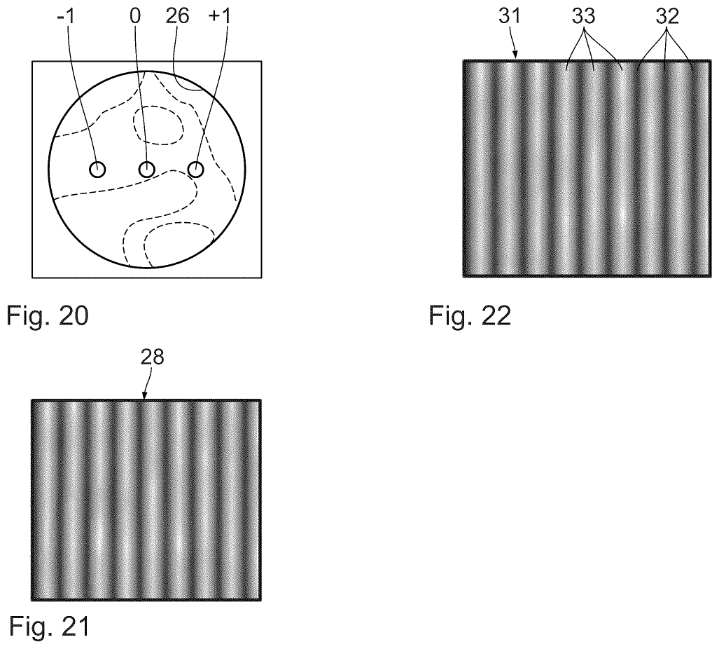

FIG. 19 shows the entrance pupil 24 and the three orders of diffraction of the diffraction spectrum 21 which are located within the entrance pupil 24 in the initial illumination angle distribution, specifically the 0th and the +/−1st orders of diffraction.

FIG. 20 shows a distribution of an intensity of the illumination/imaging light 1 in an exit pupil plane of the projection optics unit 20. An exit pupil 26 depicted in FIG. 20 arises as an image of the entrance pupil 24.

The pupils 24 (cf. FIG. 19) and 26 (cf. FIG. 20) are elliptical. The pupils 22, 24 may also have different deviations from the circular form in the case of alternative specifications by way of appropriate aperture stops 21, with the pupils possibly being at least approximately circular. A pupil radius can be calculated as a mean radius. For instance, such alternative pupils can have an elliptical embodiment with an aspect ratio between the semi-axes ranging between 1 and for example 3. The pupils 24 and 26 may also be circular in an embodiment not depicted here.

Firstly, the images of the −1st, 0th and +1st orders of diffraction and, secondly, an imaging contribution of the optical system, specifically the projection optics unit 20, contribute to the intensity distribution in the exit pupil 26. This imaging contribution which is elucidated in FIG. 20 by dashed height contours can be described by an optical system transfer function, as is yet to be explained below. Unavoidable imaging aberrations of the optical system lead to a measurable intensity of the illumination/imaging light 1 being present in the exit pupil 26, even in regions around the orders of diffraction.

The projection optics unit 20 images the test structure 5 towards a spatially resolving detection device 27 of the metrology system 2. The detection device 27 is in the form of a camera, in particular a charge-coupled device (CCD) camera or complementary metal-oxide semiconductor (CM OS) camera.

The projection optics unit 20 is embodied as magnifying optics unit. A magnification factor of the projection optics unit 20 may be greater than 10, may be greater than 50, may be greater than 100 and may even be greater still. As a rule, this magnification factor is less than 1000.

In a manner corresponding to FIG. 18, FIG. 21 shows a complex field distribution 28 of the illumination/imaging light 1 in the region of an image plane 29 in which the detection device 27 is arranged.

FIG. 22 shows an illumination/imaging light 1 intensity distribution 31, as measured in an image field 30 in the image plane 29 by the camera 27. Images of the absorber lines 6 are present in the intensity distribution 31 as substantially dark lines 32 of low intensity and images of the multilayer lines 7 are present as bright lines 33 of greater intensity in the intensity distribution 31.

The following procedure is carried out to simulate the illumination and imaging properties of the optical production system when illuminating and imaging the object, using the example of the test structure 5, by use of the optical measurement system 1 of the metrology system 2:

Firstly, at least one pupil stop 10 and, for instance, a plurality of pupil stops 10 each with different stop boundary shapes are provided for the purpose of specifying correspondingly different measurement illumination settings. This is implemented by providing pupil stops 10, for example in the style of the pupil stops 10 of FIGS. 2A to 9D, in a stop storage unit accessible to the stop interchange unit, which may be part of the displacement drive 16.

Then, a target pupil stop with a target stop boundary shape is specified proceeding from an illumination setting of the optical production system to be simulated. The target pupil stop can be an arrangement of a plurality or multiplicity of individual pupil spots or stop spots. In this case, the intensity of individual illumination spots or pupil spots generally differs between the individual spots.

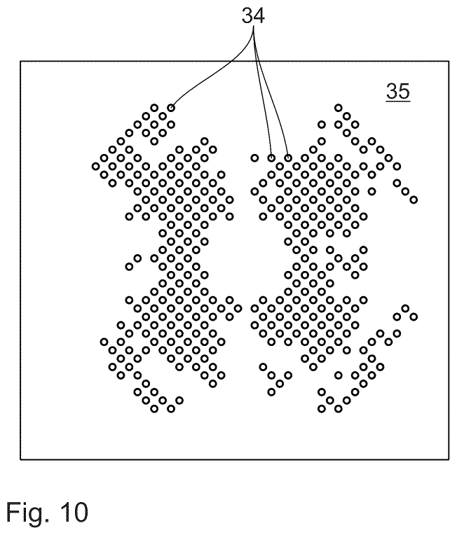

FIG. 10 shows an example of an illumination setting of the optical production system to be simulated. This production illumination setting in a pupil plane of an optical production system illumination optics unit is provided by way of a fly's eye integrator with a field facet mirror and a pupil facet mirror and comprises a plurality of intensity spots 34, arranged in grid-like fashion, in a production illumination optics unit illumination pupil plane 35. The intensity spots 34 may have different intensities, and so the illumination light from different illumination directions may be incident on the object field 3 with correspondingly different intensities.

Further examples of an illumination setting to be simulated are illumination settings that can be created by use of a specular reflector, the latter for example is described in U.S. Pat. No. 9,915,875 B2. When integrated over an object displacement direction, i.e. a scanning direction, this yields a less discrete intensity distribution rather than a distribution of intensity spots over an illumination pupil in the pupil plane.

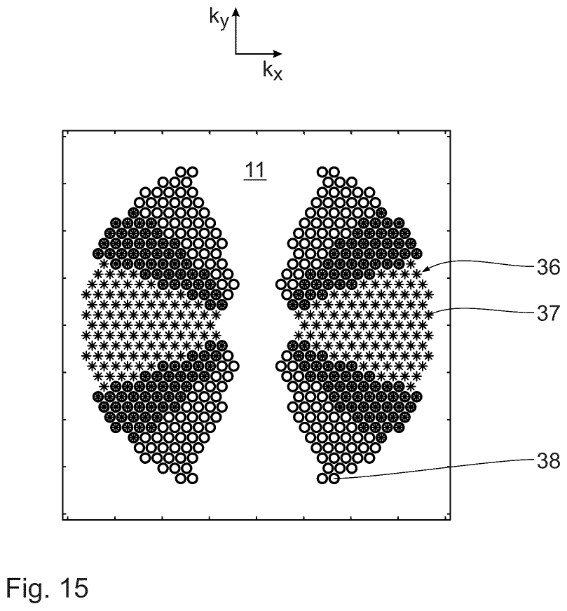

FIG. 15 likewise shows a target pupil stop 36 in a pupil plane with pupil coordinates kₓ, k_{y}, the target stop boundary shape of said target pupil stop being specified in a manner dependent on the illumination setting of the optical production system to be simulated, for example dependent on the illumination setting according to FIG. 10.

The target pupil stop 36 can be specified by way of a definition of appropriate stop aperture contours, especially continuous stop aperture contours. Such stop aperture contours can be described by polygonal chains, for example.

These continuous openings are then approximated by a finite number of pupil spots 37 within the openings. These spots are depicted in FIG. 15 by way of example.

For the specific example in FIG. 15, the aperture contour of the stop in FIG. 7A was used as measurement stop, and the aperture contour of the stop in FIG. 5A was used as target setting. The finer the grid of illumination spots, the more accurately the actual stop shape can be approximated.

FIG. 15 depicts a grid of pupil spots 37 (stars in FIG. 15) which are arranged within the specified target pupil stop 36. This grid arrangement of the pupil spots 37 can take account of shadowing, in particular by way of required connecting pieces of the pupil stop.

Proceeding from this target pupil stop 36, at least one pupil stop 10 is then selected from the provided plurality of pupil stops 10 by use of an algorithm which qualifies deviations between the respective stop boundary shape of the provided pupil stops 10 and the target stop boundary shape of the target pupil stop 36. To this end, the pupil stop 10 currently under examination during the selection (also referred to as pupil stop to be qualified below) can in turn be decomposed within its stop boundary into a plurality of pupil spots 38 arranged in grid-like fashion and represented by circles in FIG. 15.

The scope of qualification comprises determining the similarity between the target illumination pupil (also denoted “T” below) and the possible measurement stops 10 (also denoted “M” below). For instance, this can be implemented by calculating an overlap function Q.

$$Q = \frac{A ( M ⋂ T )}{A ( M ⋃ T )} - \frac{A ( M ∖ T )}{A ( M )} - \frac{A ( T ∖ M )}{A ( T )}$$

Here, A is a function for (approximately) calculating the area. The first term corresponds to the normalized area of the overlap between measurement stop and target illumination pupil. The second and third terms correspond to the normalized difference area between the measurement stop and the target illumination pupil, and vice versa. The difference area is intended to refer to the area contained only in the first pupil and not in the second.

The operators “∩”, “∪” and “\” correspond to the intersection (∩), union (∪) and relative complement (\) operators from set theory. In this case, the intersection M₁∩M₂ of the sets/areas M₁ and M₂ is intended to mean the set/area which is contained both in M₁ and in M₂, i.e. corresponds to the overlap area of M₁ and M₂. The union M₁∪M₂ of the sets/areas M₁ and M₂ describes the set/area which is contained in M₁ or M₂, i.e. corresponds to the overall area covered by M₁ or M₂. The relative complement M₁\M₂ of the sets/areas M₁ and M₂ describes the set/area which is covered by M₁ but not contained in M₂.

For instance, the area function A can be implemented as counting illumination spots in the pupil. To this end, target illumination pupil and measurement pupil are scanned using the same grid. Typically, the grid corresponds to the pupil facet grid in the scanner on which the target illumination pupil is sampled (cf. FIG. 10). Now, the number of spots present in both illumination pupils (first term in the formula above) are counted, as are the spots that are exclusive to only one of the two pupils (second and third term in the formula above). In an alternative to that, comparison of the local spot density or the mean local brightness is also conceivable.

Thus, the selection of the pupil stop 10 encompasses a comparison between the poses of pupil spots 37 of the target stop boundary shape and the poses of pupil spots 38 of the provided pupil stops 10.

Moreover, a plurality of defocus values zₘ (cf. FIG. 1) are specified as z-distances of a position of the object holder 17 from the object plane 4 (parallel to the xy-plane).

Moreover, a plurality of measurement positions (kₓ, k_{y}) of the selected pupil stop 10 are specified within the scope of the simulation method.

Now, measurement aerial images Iₘₑₐₛ(\vec{r}, zₙ, \vec{q}ₘ) are recorded in the image plane 29 at the spatial coordinates \vec{r}=x, y, in the style of intensity distributions 31 according to FIG. 22 and for a plurality of combinations of in each case one specified defocus value zₘ and one measurement position of the selected pupil stop 10, parameterized by way of an illumination direction q. This is carried out for all positions of the object holder 17 which are assigned to the previously specified defocus values zₘ. For at least one of the specified defocus values zₘ, a plurality of measurement positions (kₓ, k_{y}) of the selected pupil stop 10 are homed in on by way of the displacement drive 16 in order to make the respective recording of the measurement aerial image I(x, y).

The sequence in FIGS. 11A to 11I shows such a combination of one defocus value zₘ and a total of nine measurement positions (kₓ, k_{y}) of the pupil stop 10, with the pupil stop 10 according to FIG. 2B having been chosen here for the purpose of specifying a conventional illumination setting. Depicted in each case is the position of passage pole I of the pupil stop 10 relative to the position of the imaging pupil stop 23.

FIG. 11A shows the pupil stop 10 centered with respect to the imaging pupil stop 23. In this starting position according to FIG. 11A, the pupil stop 10 is imaged centered in the aperture of the imaging pupil stop 23.

In comparison with the imaging pupil stop 23, FIG. 11B shows the pupil stop 10 displaced from the centred position according to FIG. 11A by a specified increment in the positive kₓ-direction.

In comparison with the centred position according to FIG. 11A, the following sequence in FIGS. 11C to 11I in each case shows a further displacement of the pupil stop 10 through 45° in the circumferential direction, starting from the position according to FIG. 11B. Hence, the measurement positions according to FIGS. 11C, 11E, 11G and 11I show the pupil stop 10 in the positions of the four quadrants I to IV. The measurement positions according to FIGS. 11B, 11D, 11F and 11H show the pupil stop 10 in the Cartesian displacement positions +kₓ, +k_{y},

−kₓ. −k_{y}.

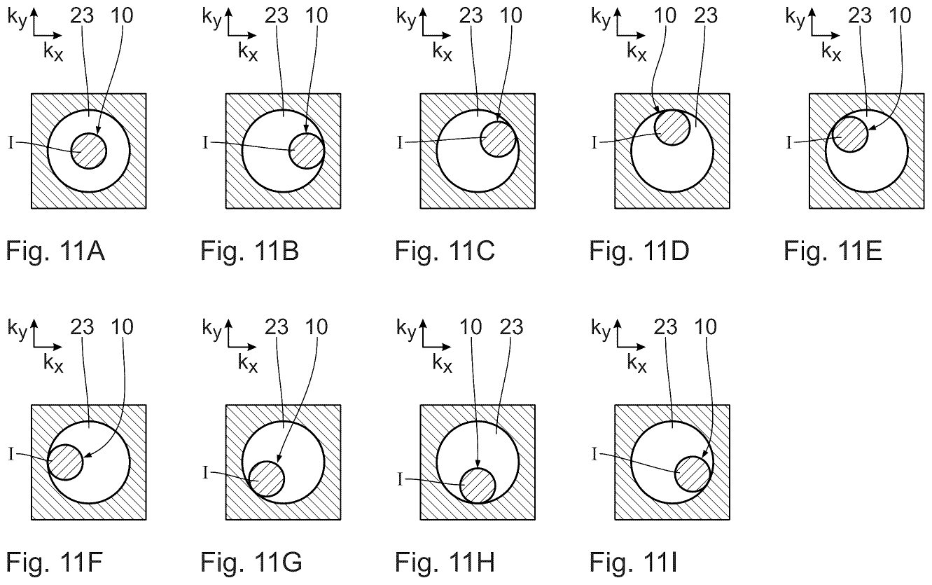

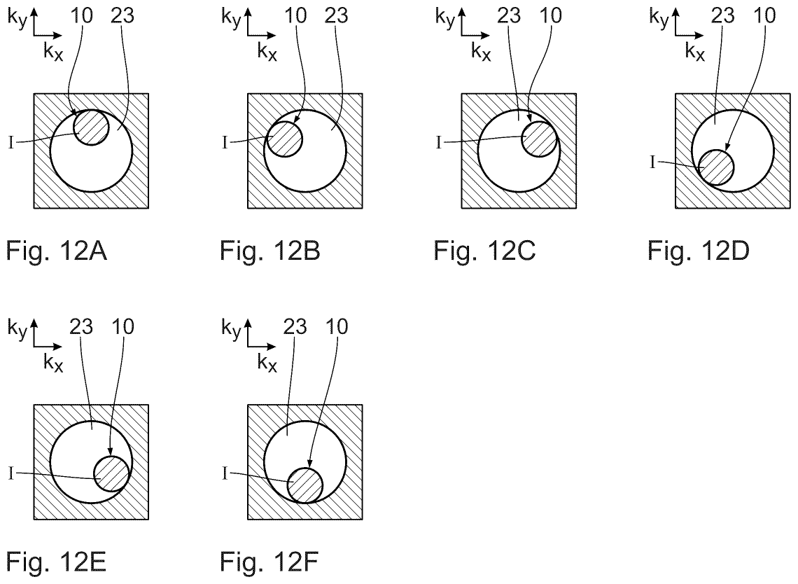

An alternative sequence of measurement positions (kₓ, k_{y}) of the pupil stop 10 is depicted in FIGS. 12A to 12F. This sequence of the measurement positions 12A to 12F corresponds to the measurement positions according to FIGS. 11D, 11E, 11C, 11G, 11I and 11H.

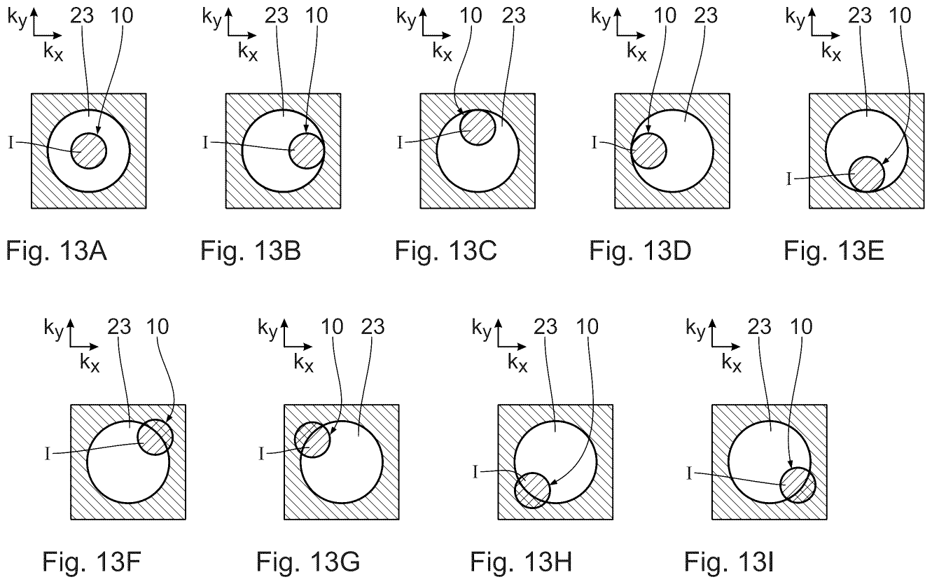

FIGS. 13A to 13I show a further variant of a sequence of measurement positions (kₓ, k_{y}) of the pupil stop 10.

FIG. 13A shows the pupil stop 10 once again centred with respect to the imaging pupil stop 23. In comparison with the imaging pupil stop 23, FIG. 13B shows the pupil stop 10 displaced from the centred position according to FIG. 13A by a specified increment in the positive kₓ-direction.

Relative to the imaging pupil stop 23, FIG. 13C shows the pupil stop 10 displaced in the positive k_{y}-direction from the centred position according to FIG. 13 by the same increment.

Relative to the imaging pupil stop 23, FIG. 13D shows the pupil stop 10 displaced by the increment in the negative kₓ-direction starting from the centred position according to FIG. 13A.

Relative to the imaging pupil stop 23, FIG. 13E shows the pupil stop 10 displaced by the specified increment in the negative k_{y}-direction starting from the centred position according to FIG. 13A.

The completed sequence of measurement positions (kₓ, k_{y}) is shown in FIGS. 13F to 13I. The circumferential positions of the pupil stop 10 relative to the imaging pupil stop 23 correspond there to the positions according to FIGS. 11C, 11E, 11G and 11I. In contrast to these positions, the pupil stop 10 in the sequence according to FIGS. 13F to 13I has been pushed so far out of the aperture of the imaging pupil stop 23 in the radial direction that only an inner part of the passage spot I of the pupil stop 10 still overlaps with the aperture of the imaging pupil stop 23. Just slightly over half of the area of the passage spot I can be traversed by the illumination light in this case. This yields a complete sequence according to FIGS. 13A to 13I with two displacement radii.

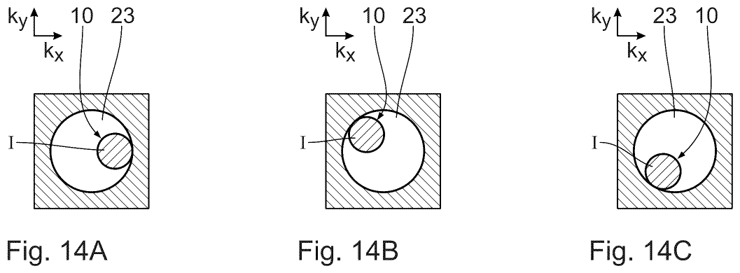

FIGS. 14A to 14C show a further variant of a sequence of measurement positions (kₓ, k_{y}) of the pupil stop 10. The measurement positions according to FIGS. 14A to 14C correspond to the measurement positions according to FIGS. 11B, 11E and 11G.

The selection of the respective measurement position sequence, or optionally a subset therefrom, is implemented on the basis of the arrangement of individual structures of the test structure 5 and/or on the basis of the illumination setting of the optical production system to be simulated. For instance, the measurement position sequence can be selected in a manner analogous to the stop selection algorithm (see above), with all stop positions of a sequence being taken into account and the sequence being selected for which the overlap of the measurement sequence with the target illumination pupil is maximal.

The poses of the pupil stop 10 which differ from the center position in terms of the relative pose with respect to the imaging pupil stop 23 are also referred to as offset measurement positions. Within the scope of a measurement position sequence, two to ten such offset measurement positions can be homed in on, this typically being two to five offset measurement positions, for example three or four offset measurement positions. The offset measurement positions can be arranged uniformly distributed in the circumferential direction. To reduce the measurement time, it is also possible to use only a subset, e.g. every second measurement position, from the measurement schemes (FIG. 11 to FIG. 14) shown.

The specified defocus values zₘ are measured with the aid of the respective measurement position sequence. In an alternative, it is possible that the entire respective measurement position sequence is used only for one defocus value or for individual defocus values zₘ, with the measurement aerial images being recorded for fewer measurement positions of the pupil stop relative to the imaging pupil stop 23 in the case of other defocus values zₘ. In extreme cases, it is possible for instance to home in on the entire measurement position sequence and record a respective measurement aerial image there for only one defocus value zₘ, whereas the measurement aerial image Iₘₑₐₛ is only recorded at one respective measurement position, in particular for the centred pupil stop 10, in the case of the other specified defocus values zₘ.

For instance, the following defocus value/measurement position combinations can be recorded: A central defocus value zₘ and a plurality of measurement positions (kₓ, k_{y}) of the pupil stop 10, i.e., in particular, a centred measurement position and a plurality of offset measurement positions, and defocus values zₘᵢₙ, zₘₐₓ maximally offset from the central defocus value on both sides, with exactly one central measurement position (kₓ, k_{y}) of the pupil stop 10 being adopted at these positions zₘᵢₙ, zₘₐₓ.

Then, a complex mask transfer function is reconstructed from the totality of measurement aerial images recorded with the selected pupil stop 10. A similar reconstruction step is also described in DE 10 2019 215 800 A1, the entire content of which is incorporated by reference.

The reconstruction is implemented within the scope of a modelled description, in which a function σ(\vec{p}, \vec{q}) reproducing the illumination directions \vec{p} passed through the pupil stop 10 is used to describe the projection optics unit 20 of the metrology system 2 with the illumination setting specified by the pupil stop 10. In contrast to the reconstruction according to DE 10 2019 215 800 A1, for example, a change in the illumination light distribution σ on account of a change in the measurement position of the pupil stop 10 is not limited to a description by way of a pure displacement vector; instead, the description of the illumination light distribution σ includes a chief ray-dependent change in effective edge contours of the pupil stop 10, dependent on the displacement position thereof. Thus, the illumination light distribution depends on, firstly, the pupil coordinate \vec{p}, which describes a basic shape of pupil stop edge contours, and on a chief ray illumination direction \vec{q}. The illumination light distribution field dependence considered thus is illustrated in more detail with the aid of the figures described below:

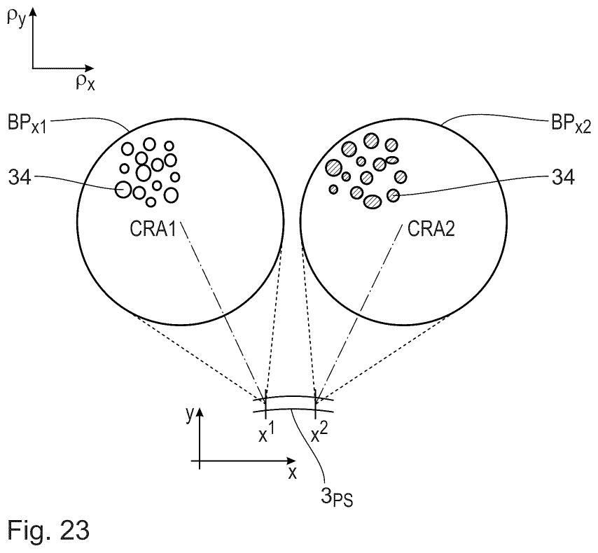

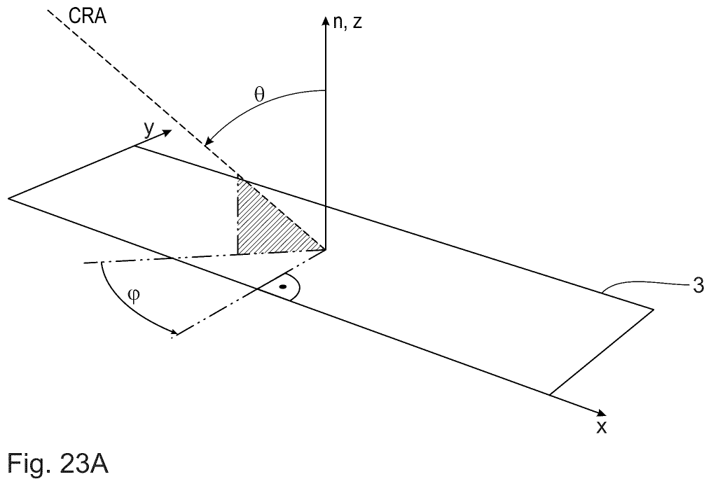

FIG. 23 schematically shows a variation of an illumination pupil BP for two different field coordinates x¹, x² in the optical production system, using the example of a projection exposure apparatus embodied as a scanner. Shown with an exaggeratedly large dependence are two illumination pupils BPₓ₁, BPₓ₂ of an illumination system in the optical production system in the style of the illumination setting from FIG. 10.

The field coordinate x extends perpendicular to an object displacement direction y, in which the object 5 in the form of a reticle is displaced during a scanning projection exposure procedure in production operation. The field coordinate x thus extends perpendicular to an object displacement direction y of the optical production system.

By way of x¹ and x², FIG. 23, bottom, depicts two different field points or field heights of the typically ring-shaped optical production system object field 3_{PS}, also referred to as EUV reticle illumination field. Vertical lines at the x-coordinates x¹, x² indicate that the depicted illumination pupils BP are the results of an integration over the y-component of the field. This models the function of the scanner projection exposure apparatus. Above the field 3_{PS}, FIG. 23 depicts the two illumination pupils BPₓ₁, BPₓ₂, i.e. two angular space illuminations which correspond to these x-coordinates and are in each case depicted centred around a chief ray CRA1 and CRA2 [chief ray angle], respectively, of the respective illumination pupil BP. The chief rays CRA1 and CRA2 differ in terms of the chief ray illumination directions, with this difference depicted very exaggeratedly in FIG. 23.

The following variables are depicted schematically in FIG. 23 with a field variation: The illumination chief ray CRAi of the respective illumination pupil BP typically varies continuously from field point to field point xⁱ of the object field 3_{PS}. Each intensity spot 34 (image of the source volume or source plasma of the EUV light source 8) of the respective EUV illumination pupil BPₓᵢ varies in terms of its pupil coordinate position ρₓ^{f,i}, ρ_{y}^{f,i}, in terms of its intensity I^{f,i} and in general also in terms of its shape and polarization, where f indicates a position in the object field 3_{PS} and i indicates the respective intensity spot 34. ρₓ, ρ_{y} are the pupil coordinates of the respective intensity spot 34.

In particular, it should be observed that the shapes of the intensity spots 34 of the respective EUV illumination pupil BPₓᵢ also vary depending on the direction of the illumination chief ray CRAᵢ. This shape dependence of the intensity spots 34 on the chief ray angle CRAᵢ can be traced back to optical system aberrations.

The pupil coordinates ρₓ, ρ_{y} used in the description of FIG. 23 correspond to the coordinates kₓ, k_{y} used further above, especially in the context of FIG. 15.

The EUV illumination pupils BPₓᵢ thus vary in respect of the above-explained parameters as a function of the field height xⁱ.

FIG. 23A also illustrates angles θ, φ used for characterizing an incidence of a chief ray CRA on the object field 3 and serving to parameterize the chief ray angle of incidence in two angle dimensions. Here, θ is the angle of incidence of the chief ray CRA relative to a normal n to the object field 3, i.e. to a normal to the object plane 4 parallel to the xy-plane.

φ denotes an azimuth angle between a perpendicular to the object field coordinate x, once again through the object field point of incidence of the chief ray CRA, and a projection line of the chief ray CRA in the xy-plane.

The orientation of the chief ray CRA with respect to the object field 3 can be described exactly by way of the two angles θ and φ.

In general, stop shadowing effects predominantly come to bear at angles θ≥4° and φ≥10°.

The angle φ specifies a deviation of the chief ray from a meridional trajectory (parallel to the yz-plane).

The metrology system 2 measures a portion of the reticle, i.e. of the test structure 5 in the form of an aerial image. A chief ray CRA of the production system is simulated with the aid of the optical measurement system of the metrology system 2, and so a variation of a contour of the pupil stop 10 in the respective measurement position arises as a function of a simulated chief ray angle CRAi; this is a consequence of the inclination of the respective production system chief ray angle CRAi, i.e. of the respective chief ray illumination direction.

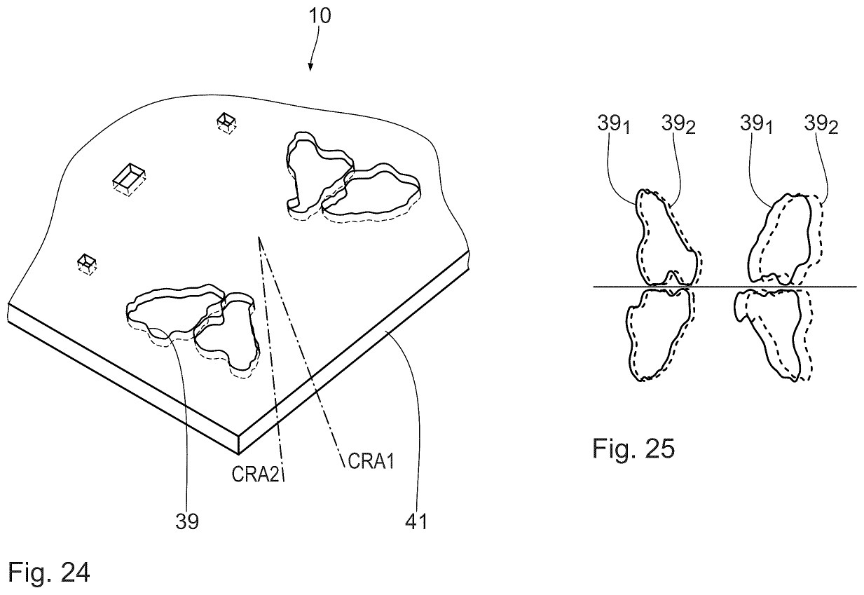

FIGS. 24 and 25 illustrate this effect.

FIG. 24 shows a stop contour of an example of the pupil stop 10. A boundary 39 of stop apertures of the pupil stop 10 which can be used for simulating an optical production system dipole illumination setting, for example, has a free-form design which is slightly reminiscent of an actual dipole geometry of the production illumination setting to be simulated.

In addition, FIG. 24 illustrates additional stop apertures, which are adjustment aids for positioning the pupil stop 10 in the pupil plane 11 and also referred to as alignment marker openings.

The pupil stop 10 according to FIG. 24 is realized by creating the stop apertures in a stop main body 41 of finite thickness.

Further, FIG. 24 by way of example plots two different chief rays (center of a beam of illumination light 1 illuminating the pupil stop 10 from below) CRA1 and CRA2 with different chief ray illumination directions. The two chief rays CRA1, CRA2 belong to different field points.

The finite thickness of the stop main body 41, inter alia, causes a slight angular space offset of the contours of the corresponding illumination pupil when the chief ray CRAi is varied, as depicted schematically in FIG. 25. An effective stop boundary under illumination with the chief ray angle CRA1 is depicted at 39₁, and an effective stop boundary under illumination with the chief ray angle CRA2 is depicted at 39₂.

In general, the fact that the intensities, contours and polarization properties in the illumination pupil vary when the illumination directions of the chief rays CRAi are varied also applies to the illumination pupil of the metrology system 2. In principle, the respective imaging optics units of the metrology system 2 and optical production system to be simulated also have a field variation. The upshot is that, in the optical production system, an exit pupil of the imaging optics unit, which images the object field or illumination field in the image field, regularly varies as a function of the field coordinate. This exit pupil variation is independent of the respective optical production system illumination pupil. In a manner similar to the situation presented above, contour, polarization and intensity variations arise in the metrology system 2 for different illumination directions of the chief rays CRAi.

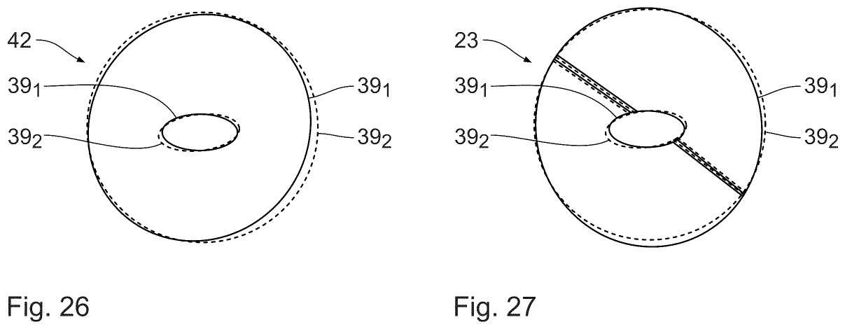

FIGS. 26 and 27 illustrate this relationship.

FIG. 26 shows stop contours of an aperture stop 42 used in the exit pupil of the optical production system imaging optics unit.

FIG. 27 shows stop contours of the aperture stop 23 in the metrology system 2, once again for two field locations which correspond to the field locations in FIG. 26.

An effective boundary of an aperture stop 42 for a first chief ray angle CRA1 is depicted in FIG. 26 at 39₁ (solid line). The stop boundary of the aperture stop 42 for a further, different chief ray angle CRA2 is depicted at 39₂ (dashed line).

Accordingly, FIG. 27 also depicts the effective stop boundaries 39₁, 39₂ of the aperture stop 23 for the two chief ray angles CRA1 and CRA2.

A variation in the field point leads to a change in the aperture boundary, intensity distribution (apodization), and phase and polarization effect; this can be described by way of a Jones pupil J_production_system_1/2 or J_metrology_system_1/2 for two field & chief ray variants CRA1 and CRA2 in the optical systems.

A person skilled in the art finds details in this respect and, in particular, in respect of the Jones formalism in M. Totzeck, P. Gräupner, T. Heil, A. Göhnermeier, O. Dittmann, D. Krähmer, V. Kamenov, J. Ruoff, and D. Flagello, “How to describe polarization influence on imaging,” Proc. SPIE 5754, 23-37 (2005), and in the textbook “Field Guide to Polarization” by E. Collett, SPIE Press Book, 2005.

Thus, as a rule, the following dependencies have to be considered when simulating aerial image properties of the optical production system using the metrology system 2, especially in the sub-nanometer range, i.e. on a picometer scale:
a field dependence of an optical production system illumination pupil;
a chief ray angle dependence of the metrology system illumination pupil;
a field dependence of an exit pupil of the optical production system imaging optics unit;
a chief ray angle dependence of an exit pupil of the imaging optics unit 20 in the metrology system 2.

These effects can be considered in the simulation method described herein, to be precise both during the reconstruction, as described below, and during the forward propagation, as described below.

In a manner corresponding to the explanations given above in relation to FIGS. 24 and 25, FIGS. 28A to 28D illustrate deviations between effective stop boundaries of the pupil stop 10 on account of different illumination directions of chief rays CRA1, CRA2.

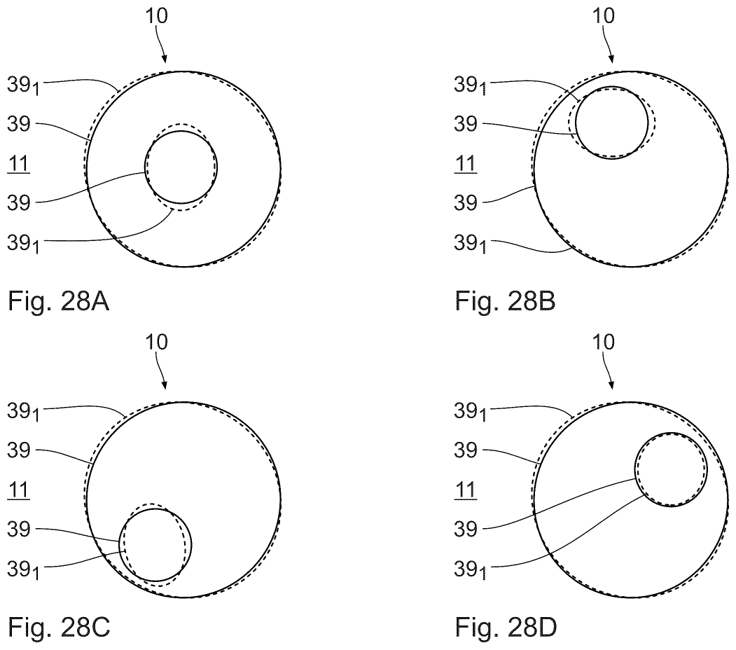

The finite thickness of the stop main body 41 leads to differences in the effective stop contours of the respective pupil 10 in the measurement positions according to FIGS. 11A (FIG. 28A), 11E (FIG. 28B), 11G (FIG. 28C) and 11C (FIG. 28D).

In FIGS. 28A to 28D, the boundary 39 of the respective pupil stop 10 is depicted using a solid line for an ideal shape 39 and using a dashed line as an effective stop boundary 39₁ for a specific illumination direction of a chief ray CRA. For instance, this respective effective stop boundary 39₁ arises on account of shadowing effects, as explained above. It should be observed that in the various measurement positions depicted in FIGS. 28A to 28D only the inner stop boundary varies in a manner dependent on the measurement position; by contrast, the variation of the outer stop boundary is independent of the measurement position since the same outer boundary is present here in each case in a rotationally invariant fashion.

For typical measurement sequences by the metrology system 1, a plurality of focus stacks (variation of zₘ, cf. FIG. 1) are recorded with the same position of the aperture stop 23 but with a different measurement position of the pupil stop 10. While the effective stop contour of the aperture stop 23 remains the same, the effective stop boundary of the pupil stop 10 of the metrology system 2 is different in the respective measurement positions, as illustrated by the comparison of the effective stop boundaries 39₁ in FIGS. 28A to 28D.

The (known) effective aperture contours 39ᵢ can be taken into account when reconstructing the complex mask spectrum. To this end, the effective aperture contours 39ᵢ can for instance be ascertained by optical simulations (e.g. by way of ray tracing) of the illumination and projection optics unit. Further, it is also possible to measure these directly by way of a pupil image. For instance, Bertrand optics can be used to this end.

Each illumination direction creates a complex-valued field distribution m(\vec{r}, \vec{p}) (cf. the field distribution 19 in FIG. 17) in the object plane 4 as a result of interaction with the test structure 5. This distribution depending on not only the field point \vec{r} but also the illumination direction \vec{p} is explicitly taken into account here. The field distribution interferes in the entrance pupil 24 of the imaging optics unit 20 to form a likewise complex-valued diffraction spectrum M(\vec{k}, \vec{p}) (cf. diffraction spectrum 21 in FIG. 19) corresponding to the Fourier transform of the field distribution m of the test structure 5. The propagation through the projection optics unit 20 of the metrology system 2 can be modelled by multiplication with the known, complex-valued transfer function P of the projection optics unit 20:

$$P \{ \vec{k} , z ) = NA ( \vec{k} ) {e}^{i \frac{2 π}{λ} z \sqrt{1 - {\vert k \vert}^{2}}} \qquad ( 1 )$$

Here,

$$NA ( \vec{k} ) = \begin{matrix}1 for \vert k \vert \leq NA \\ 0 for \vert k \vert > NA\end{matrix}$$

is the curtailment by the numerical aperture of the imaging optics unit 20, i.e. by the imaging pupil stop 23, and

$${e}^{i \frac{2 π}{λ} z \sqrt{1 - {\vert k \vert}^{2}}}$$

is the wavefront error caused by a defocus z (displacement by the object holder 17). Now, for this curtailment by the aperture stop 23, the effective stop boundary 39ᵢ is set in accordance with the explanations relating to FIG. 27 in particular.

The propagated spectrum (cf. FIG. 21) now interferes to form the field distribution 28 in the image plane 29. The camera measures the intensity 31 of the field distribution 28 integrated over all illumination directions of the illumination system. Thus, the aerial image of the test structure 5 measured with the defocus z and the illumination direction \vec{q} can be described as follows and can be simulated by inserting a candidate for the mask spectrum M:

$${I}_{sim} \{ \vec{r} , z , \vec{q} ) = \int d \vec{p} σ ( \vec{p} , \vec{q} ) {\vert \int d \vec{k} M ( \vec{k} , \vec{p} ) P ( \vec{k} , z ) {e}^{i \vec{k} \vec{r}} \vert}^{2} \qquad ( 2 )$$

In this case, \vec{r} is the xy-position of the intensity measurement, i.e. the respective pixel of the camera 27.

\vec{q} is the illumination direction and \vec{p} is the pupil coordinate. An illumination direction \vec{q} corresponds to a center of a stop aperture of the respective pupil stop 10 in the respective measurement position.

For σ(\vec{p}, \vec{q}), the effective stop boundaries of the pupil stops 10 at the different measurement positions are used in accordance with the explanations given above, especially in the context of FIGS. 28A to 28D.

The goal now is to determine the mask spectrum M(\vec{k}, \vec{p}). In this case, \vec{k} is the pupil coordinates in the entrance pupil 24 of the projection optics unit 20 and \vec{p} is the illumination direction.

The Fourier transform of the respective mask spectrum is the associated mask transfer function.

The reconstructed spectra can then be used to calculate the aerial image for any other illumination setting σ_{target} (\vec{p})) and any defocus z_{target}. This is also referred to as forward propagation.

The determination of M(\vec{k}, \vec{p}) can be formulated as an optimization problem: Sought are the spectra M(\vec{k}, \vec{p}) for which there is a minimum deviation F between the simulated aerial images and the aerial images Iₘₑₐₛ measured at the defocus positions z₁, z₂ . . . z_{N} and the illumination directions \vec{q}₁, \vec{q}₂ . . . \vec{q}_{M}. The following optimization problem should be solved:

$${min}_{M ( \vec{k} , \vec{p} )} F = {min}_{M ( \vec{k} , \vec{p} )} {\sum }_{n} {\sum }_{m} \int d \vec{r} {\vert {I}_{sim} ( \vec{r} , {z}_{n} , {\vec{q}}_{m} ) - {I}_{meas} ( \vec{r} , {z}_{n} , {\vec{q}}_{m} ) \vert}^{2} \qquad ( 3 )$$

A separate spectrum is reconstructed for each illumination direction \vec{p}.

A simulated aerial image Iₛᵢₘ for the target illumination setting σ_{target} and the target defocus z_{target} can be calculated using the reconstructed directionally dependent spectrum:

$${I}_{sim} ( \vec{r} , z , {x}^{m} ) = \int d \vec{p} {σ}_{target} ( \vec{p} , {x}^{m} ) {\vert \int d \vec{k} M ( \vec{k} , \vec{p} ) P ( \vec{k} , {z}_{target} , {x}^{m} ) {e}^{i \vec{k} \vec{r}} \vert}^{2} \qquad ( 4 )$$

The setting for the target illumination setting σ_{target} now also depends on the field position x^{m} of an intensity measurement position in the object field 3. This dependence corresponds to the variation depicted in FIG. 23 by way of example.

Thus, an actual intensity distribution BPₓₘ in the optical production system illumination pupil BP is used for each intensity measurement position. This intensity distribution can be ascertained from an optical simulation of the optical production system or from a measurement of an optical production system illumination unit. This actual intensity distribution in the optical production system illumination pupil is assumed to be known.

A dependence of an exit pupil contour of the optical production system imaging optics unit on, firstly, the field position and/or on the chief ray angle can be taken into account by way of a field-dependent transfer function of the optical production system imaging optics unit:

$$P ( \vec{k} , z , {x}^{m} ) = {NA}_{Scanner} ( \vec{k} , {x}^{m} ) {e}^{i \frac{2 π}{λ} z \sqrt{1 - {\vert k \vert}^{2}}} \qquad ( 5 )$$

Here, NA_{Scanner}(\vec{k}, x^{m}) is the description of the stop boundary 39ₘ of the optical production system aperture stop 42, dependent on the field pose x^{m} (cf. also the above description in relation to FIG. 26).

The reconstruction thus includes that profiles of edge contours of the pupil stops 10 at the respective measurement position, i.e. of measurement illumination settings specified by stop contours 39 of the pupil stop 10, change in a manner which is dependent on a respective displacement position of the pupil stop 10 and which goes beyond a pure displacement of the edge contours.

Equation (4) then allows comparison between the simulated aerial image Iₛᵢₘ and the respectively measured aerial image Iₘₑₐₛ, and this can be used to reconstruct the mask spectrum M and, accordingly, the complex mask transfer function.

From Equation (4), the 3-D aerial image can be calculated with the aid of the reconstructed mask transfer function M and the illumination setting σ_{target} of the optical production system. In this way, it is possible to ascertain what the aerial image of the test structure 5 would look like if it were imaged by the optical production system.

As an alternative to the method described in the previous section, a correction approach analogous to DE 10 2019 206 651 A1 is also possible in place of a completely synthetic calculation of the images by propagating the reconstructed mask spectrum. To this end, a correction term Δ is calculated:

$$Δ = {I}_{sim} ( \vec{r} , z , {x}^{m} ) - {I}_{sim} ( \vec{r} , z , \vec{q} ) \qquad ( 6 )$$

The two terms Iₛᵢₘ(\vec{r}, z, x^{m}) and Iₛᵢₘ(\vec{r}, z, \vec{q}) correspond to those in Equations (4) and (2) above. In this context, measurements may be performed for the same focus poses and illumination stop positions as for the target settings. In an alternative, it is also possible to correct from one focus pose to another or else correct different illumination settings with the aid of the correction approach.

The correction term Δ corresponds to the difference in the aerial images created by the CRA/field dependence. Thus, the CRA/field dependence can be corrected as follows:

$$I ( \vec{r} , z , {x}^{m} ) - {I}_{meas} ( \vec{r} , {z}_{n} , {\vec{q}}_{m} ) + Δ \qquad ( 7 )$$

In this correction approach, systematic/constant errors compensate one another in the mask spectrum reconstruction, i.e. the same deviations in Iₛᵢₘ(\vec{r}, z, x^{m}) and Iₛᵢₘ(\vec{r}, z, \vec{q}), and do not make an unwanted contribution to the final image. As a result, it is possible to obtain effects/properties in the measurement data even if these are not taken into account in the object reconstruction imaging model. An example are 3-D mask effects in a reconstruction with a simple imaging model without explicit consideration of 3-D mask effects. In the limit case of a reconstruction with a negligible residue, i.e. F→0 in Equation (3), both methods (propagation and correction approach) are equivalent.

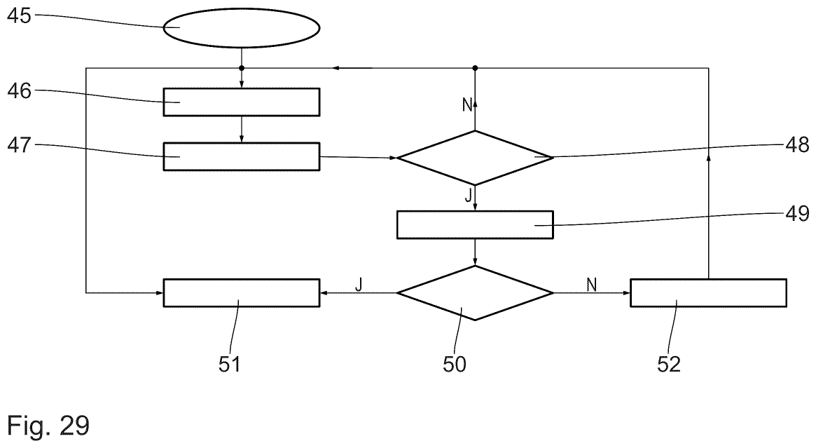

For the pupil stop 10 of the metrology system 2, the simulation method can make use either of stop basic shapes corresponding to those already explained above, especially in the context of FIGS. 2 to 9, or of at least one pupil stop 10 whose stop boundary was optimized according to a method as described below, which is described below on the basis of FIG. 29:

In a specification step 45, firstly a starting stop shape of the sigma stop 10, 10^{dc}, is selected as an initial design candidate for the simulation.

In the context of the optimization, this starting stop shape 10^{dc} is modified in a modification step 46, such that a modification stop shape 10^{dcnew} that is slightly changed in regard to its boundary shape arises in a creation step 47.

In a checking step 48, a check is then made to establish whether this modification stop shape 10^{dcnew} satisfies at least one fabrication boundary condition with regard to the fabrication of this modification stop shape 10^{dcnew}. If the checking step 48 reveals that at least one marginal check portion of the modification stop shape 10^{dcnew} does not satisfy the fabrication boundary conditions (decision “N” of the checking step 48), the modification step 46 and the creation step 47 are repeated on the basis of the last valid design candidate. This is done until the checking step 48 for a modification stop shape 10^{dcnew} then given reveals compliance with the specified fabrication boundary conditions (decision “Y” of the checking step 48).

An ascertainment step 49 then involves communicating the match quality between the illumination and imaging properties of the optical production system and the illumination and imaging properties of the optical measurement system.

A value of at least one merit function is calculated in the context of this match quality ascertainment. Said merit function is influenced by a comparison of optical illumination and imaging parameters between a pupil overlap region of an illumination pupil and an imaging pupil of the optical production system, on the one hand, and a corresponding pupil overlap region of an illumination pupil with a used stop shape of the sigma stop 8 and an imaging pupil with a used NA aperture stop 11 of the optical measurement system.

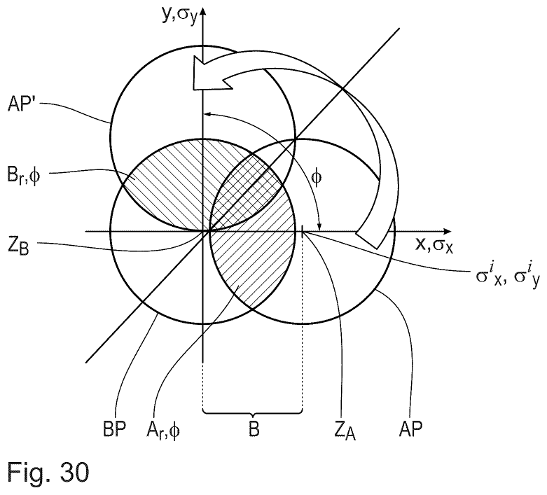

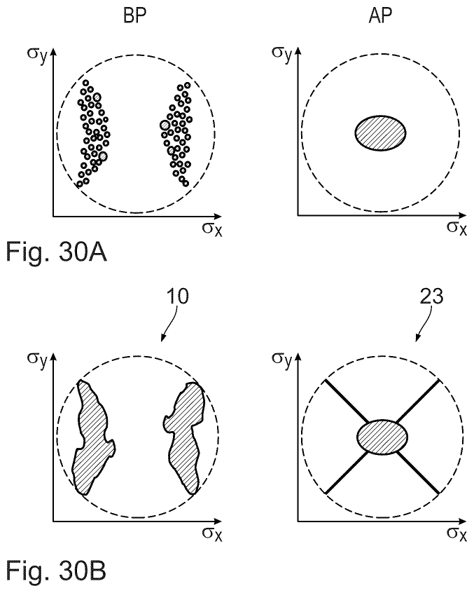

FIG. 30 shows such a pupil overlap region A_{r,ϕ} between an illumination pupil BP and an imaging pupil AP.

A center Z_{Ar,ϕ} of the exit pupil AP lies at Cartesian coordinates σₓⁱ, σ_{y}ⁱ. Instead of Cartesian coordinates σₓ, σ_{y}, it is also possible to choose polar coordinates, likewise illustrated in FIG. 30. In this case, σ_{ϕ} denotes the distance between a center Z_{B} of the illumination pupil BP and the center Z_{A} of the exit pupil AP. Φ denotes the angle between the distance σ_{ϕ} and for example the σ_{y}-axis, as depicted in FIG. 30. In the case illustrated, ϕ is 90°.

In the context of ascertaining the match quality with the aid of such a pupil overlap region A_{r,ϕ}, the overlap at various support points σₓⁱ, σ_{y}ⁱ that are scanned is assessed. The following assessment terms are used in this case:

$${D}_{r , ϕ} = {\int }_{{A}_{r , ϕ}} d {σ}_{x} d {σ}_{y} I ( {σ}_{x} , {σ}_{y} ) \qquad ( 8 )$$

$${T}_{r , ϕ} = {\int }_{{A}_{r , ϕ}} d {σ}_{x} d {σ}_{y} {σ}_{ϕ} ( {σ}_{x} , {σ}_{y} ) I ( {σ}_{x} , {σ}_{y} ) \qquad ( 9 )$$

D here is a term describing a simple summation of the intensities I(σₓ, σ_{y}) over the respective pupil overlap region A_{r,ϕ}. This D term (according to Equation (8)) correlates with an image dimension CD (critical dimension), i.e. a width of a structure along a specified direction.

Reference is made to U.S. Pat. No. 9,176,390 B in the context of the definition of the parameter CD. The content of U.S. Pat. No. 9,176,390 is incorporated by reference.

The T term (according to Equation (9)) represents an integral over the overlap region A, said integral again being weighted with the distance value σ_{ϕ}. For this formulation of the T term, it is assumed for simplification that the exit pupil has no apodization. This T term correlates with the imaging telecentricity imaging parameter. This can include a sensitivity of an object structure offset as a function of a defocus position of a substrate onto which the object is imaged.

For a given pupil stop shape of the pupil stop 10, the following optimization rules are applied when ascertaining the match quality for all possible overlap regions A_{r,ϕ}:

$${D}_{r , ϕ}^{dc} - {D}_{r , ϕ}^{t} = 0 for all value pairs r , ϕ \qquad ( 10 )$$

$${T}_{r , ϕ}^{dc} - {T}_{r , ϕ}^{t} = 0 for all value pairs r , ϕ \qquad ( 11 )$$

In this case, dc stands for the respective design candidates, i.e. for the currently considered stop shape of the pupil stop 10. t stands for the target illumination pupil of the optical production system, i.e. in particular of a projection exposure apparatus in the form of a scanner.

The optimization rules in accordance with Equations (10) and (11) are not attained as a rule. When ascertaining the match quality, the stop shape of the design candidate dc is varied until the optimization rules (10), (11) yield minimum values.

Besides the optimization variables D and T, further variables correlated with further illumination and/or imaging parameters can also be used when ascertaining the match quality. One example of such a variable is:

$${HV}_{r , ϕ} = {D}_{r , ϕ} - {D}_{r , ϕ - 90 °} = {\int }_{{A}_{r , ϕ}} d {σ}_{x} d {σ}_{y} I ( {σ}_{x} , {σ}_{y} ) - {\int }_{{B}_{r , ϕ}} d {σ}_{x} d {σ}_{y} I ( {σ}_{x} , {σ}_{y} ) \qquad ( 12 )$$

This HV term correlates with an imaging variable “HV asymmetry”, which quantifies a difference in the critical dimensions (CDs) along a vertical and along a horizontal dimension. The HV term may be of interest depending on the structures to be imaged on the object 5; for example in the case of horizontal or vertical lines to be imaged, in particular having the same periodicity and the same target CD, or else in the case of so-called contact holes, i.e. structures having an xy-aspect ratio in the region of 1. An HV asymmetry can then be understood as the difference between the two CDs, i.e. CDₕ−CDᵥ in the case of horizontal (h) and vertical (v) lines or CDₓ−CD_{y} in the case of contact holes having extents in the x- and y-directions.

Ascertaining the HV term according to Equation (12) above involves calculating the difference between two D terms according to Equation (8) at the location of two defined overlap regions A_{r,ϕ} and B_{r,ϕ} which are rotated with respect to one another by 90° about the coordinate origin Z_{B} (cf. FIG. 30). In order to calculate the integral in the overlap region, the overlap between for example the entrance pupil BP and an exit pupil AP′ correspondingly rotated by 90° is taken into consideration.

For the HV term, too, there is then a corresponding optimization rule:

$${HV}_{r , ϕ}^{dc} - {V}_{r , ϕ}^{t} = 0 for all value pairs r , ϕ \qquad ( 13 )$$

After comparison calculation has been carried out, the overlap regions A_{r,ϕ} used cover the entire illumination pupil of, on the one hand, the optical production system and, on the other hand, the illumination optics unit 9 of the metrology system 2.

FIGS. 30A and 30B show two pupil pairs of, on the one hand, the optical production system (FIG. 30A) and, on the other hand, the optical measurement system of the metrology system 2 (FIG. 30B), which are compared with one another in the context of the match quality ascertainment explained above in the context of FIG. 30, in particular.

FIG. 30A shows on the left an illumination of an illumination pupil for an x-dipole illumination setting. FIG. 30A shows on the right an exit pupil of the projection optics unit of the optical projection system with a central, approximately elliptical pupil obscuration.

The illumination setting to be simulated (cf. FIG. 30A on the left) of the optical production system can be composed of a multiplicity of individual spots in the illumination pupil, corresponding to a faceted configuration of an illumination optics unit of the optical production system, for example a configuration having a field facet mirror and a pupil facet mirror or a configuration in which a MEMS mirror configuration is used within the illumination optics unit. The size of the respective individual spot in FIG. 30A on the left is a measure of the brightness of this individual spot, i.e. of the illumination intensity from the illumination direction assigned to this individual spot.

FIG. 30B shows on the left a target stop shape—obtained by use of the optimization method—of the pupil stop 10 for the simulation of the illumination and imaging properties of the optical production system with the illumination setting and the exit pupil according to FIG. 30A. FIG. 30B shows on the right the exit pupil of the imaging optics unit of the optical measurement system with the central obscuration that is created by way of the aperture stop or NA stop 23.

A merit function E can be used during the match quality ascertainment since, in general, the match rules according to Equations (10), (11) and (13) do not all become 0 at the same time. This merit function can be written as weighted error minimization in the usual way as:

$$E ( I ( {σ}_{x} , {σ}_{y} ) ) = {w}_{D} {\sum }_{i , ϕ} {( {D}_{i , ϕ} ( I ( {σ}_{x} , {σ}_{y} ) ) - {D}_{i , ϕ} ( {I}^{t} ( {σ}_{x} , {σ}_{y} ) ) )}^{2} + {w}_{T} {\sum }_{i , ϕ} {( {I}_{i , ϕ} ( I ( {σ}_{x} , {σ}_{y} ) ) - {T}_{i , ϕ} ( {I}^{t} ( {σ}_{x} , {σ}_{y} ) ) )}^{2} + … \qquad ( 14 )$$

I here denotes the stop shape of the pupil stop 10^{dcnew} which is intended to be assessed by means of the merit function. I^{t} denotes the target illumination pupil of the optical production system, this being the intended target of optimization. D and T denote the assessment terms discussed above in the context of Equations (10) and (11). In addition, the merit function E can for example also be supplemented by the assessment term HV (cf. Equations (12) and (13)).

The merit function I can additionally be supplemented by the requirement for a minimum transmission of the pupil stop 10^{dcnew}.

Besides the target illumination pupil of the optical production system, the ascertainment step 49 can also be influenced by a pupil transfer function of the optical production system and a pupil transfer function of the optical measurement system of the metrology system 2.

For this purpose, the D term defined above in the context of Equation (8) can be written as follows:

$${D}_{r , ϕ} = {\int }_{- ∞}^{+ ∞} {\int }_{- ∞}^{+ ∞} d {σ}_{x} d {σ}_{y} I ( {σ}_{x} , {σ}_{y} ) {P}_{r , ϕ} ( {σ}_{x} , {σ}_{y} )$$

P here is an apodization function, i.e. an energetic proportion of the pupil transfer function.

An apodization of the exit pupil can then be taken into account by this means.

In the course of the ascertainment step 49, compliance with an optimization criterion is queried in an optimization query step 50. One example of such an optimization criterion is the Boltzmann criterion of simulated annealing:

$$satisfied by r < P ( d c , d {c}_{new} ) with P ( d c , d {c}_{new} ) = {e}^{- β ( E ( ( d {c}_{new} ) - E ( d c ) )}$$

In this case, r is a uniformly distributed random number from the interval [0, 1[ (the exact numerical value “1” is thus excluded in this interval) and β is a control parameter that increases further and further in the course of the simulated annealing optimization. E(dc_{new}) and E(dc) are the merit functions that arose for the stop shapes of the pupil stop 10 during the last and during the preceding optimization step.

Insofar as the Boltzmann criterion is satisfied, i.e. the optimization has not yet concluded (decision Y in the query step 50), the current stop shape 10^{dcnew} is set as initial stop shape 10^{dc} for the next modification, which is effected in a specification step 51. The control parameter β is also increased in the specification step 51. The optimization criterion is thus intensified in the context of the specification step 51. Afterwards, the method continues with the modification step 46, and steps 47 to 50 are repeated until the optimization query step 50 reveals that either the Boltzmann criterion is no longer satisfied or the control parameter β is greater than a specified value (query result N in the query step 50).

If, therefore, the optimization criterion has then been attained in the optimization query step 50 (query result N), the pupil stop 10 with the target stop shape that occurred with the smallest merit function value E in the optimization is fabricated in a fabricating step 52.

FIG. 24 shows such a target stop shape 39.

Exactly one pupil stop 10, which was optimized as explained above in the context of FIGS. 29 to 30B, can be used for each optical production system illumination setting.

Individually optimized stops can be designed for a specified selection of field points xⁱ, e.g. three field points (left x-field edge, field center, right x-field edge), and so the contributions of, firstly, the optical production system and, secondly, the metrology system 2 which are valid for this field point xⁱ or for this illumination direction of the respective chief ray CRAi are taken into account more completely, and there is an accordingly improved simulation of the optical production system aerial image. This specification of individual optimized stop boundaries can be implemented accordingly for the pupil stop 10, for the aperture stops 23 and also for both stops 10, 23.

For instance, the three pupil stops 10 and optionally three aperture stops 23 optimized thus are then available for the metrology system 2. In a manner fitting to the field point x^{m} to be measured in the object field 3, it is then possible to use the corresponding stop or the corresponding stop pair of pupil stop and aperture stop.

If there is no coincidence between a field point x^{m} to be measured and a specified field point for which the respective stop was optimized in respect of its boundary, then it is possible to use a compensation rule. An example of such a compensation rule is:

$${〈 A ( x , y ) 〉}^{m} = {A ( x , y )}^{r} \frac{Δ {x}^{m - l}}{Δ x} + {A ( x , y )}^{l} \frac{Δ {x}^{r - m}}{Δ x} \qquad ( 15 )$$

Here, A(x, y) denotes the aerial image measured by the metrology system 2.

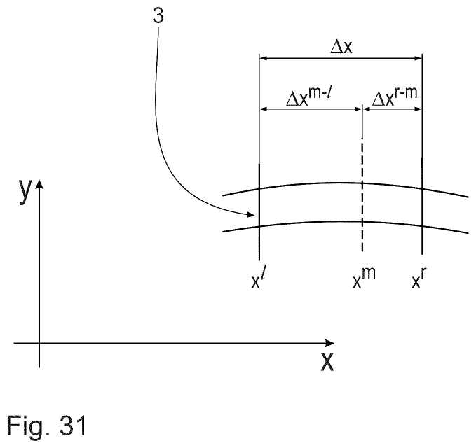

FIG. 31 shows the definitions of the distances Δx according to above Formula (15). The index m denotes the field point on the mask where a detail should be measured. No dedicated stop is available for this field point in the object field 3. Now, two aerial images are recorded at the point x^{m}: once with the stop designed and present for a field point x^{l} adjacent to the left, and once with the stop designed and present for a field point x^{r} adjacent to the right. Weighting is simply linear with the corresponding relative distances, as shown in the formula above. In the limit case where x^{m} approaches e.g. x^{r}, the aerial image A(x, y)^{r} is thus obtained with an ever-higher weighting.

An assumption that can be made for the illumination light distribution σ(\vec{p}, \vec{q}) within the scope of solving the optimization problem according to Equation (3) above is that a displacement of the illumination stop by a vector \vec{q} yields a corresponding displaced illumination light distribution, i.e.:

$$σ ( \vec{p} , \vec{q} ) = σ ( \vec{p} - \vec{q} ) \qquad ( 16 )$$

\vec{p} is the pupil coordinate in this case.

The optimization problem according to Equation (3) above then supplies a mask spectrum (M(\vec{k}, \vec{p}). Aerial images for the target illumination setting (scanner pupil) σ_{target} (p) and target defocus z_{target} can be calculated from this:

$${I}_{sim} ( r , z ) = \int dp {σ}_{target} ( p ) {\vert \int dk M ( k , p ) P ( k , {z}_{target} ) {e}^{ikr} \vert}^{2} \qquad ( 17 )$$

A part from the lack of field height dependence, Equation (17) above corresponds to Equation (4) above.

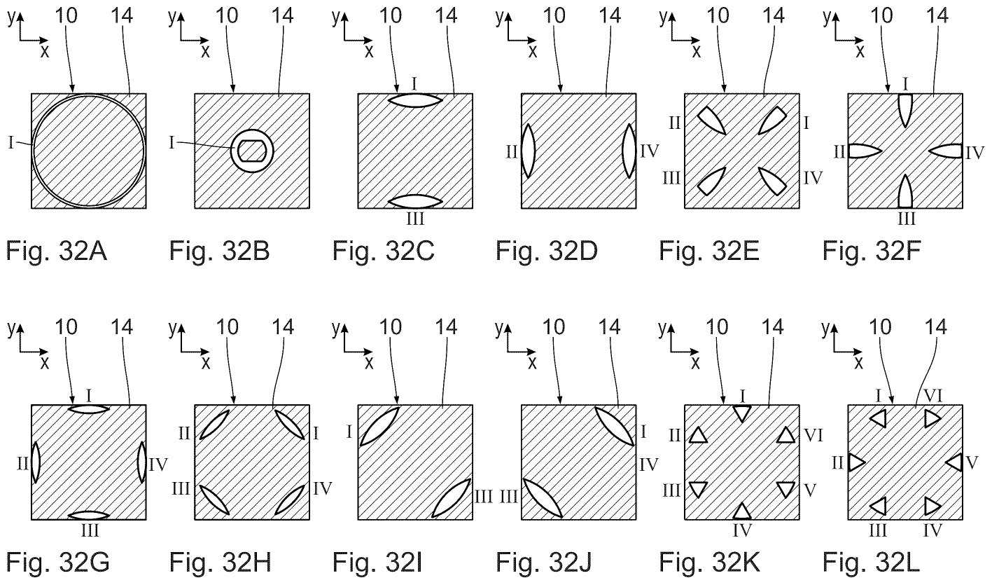

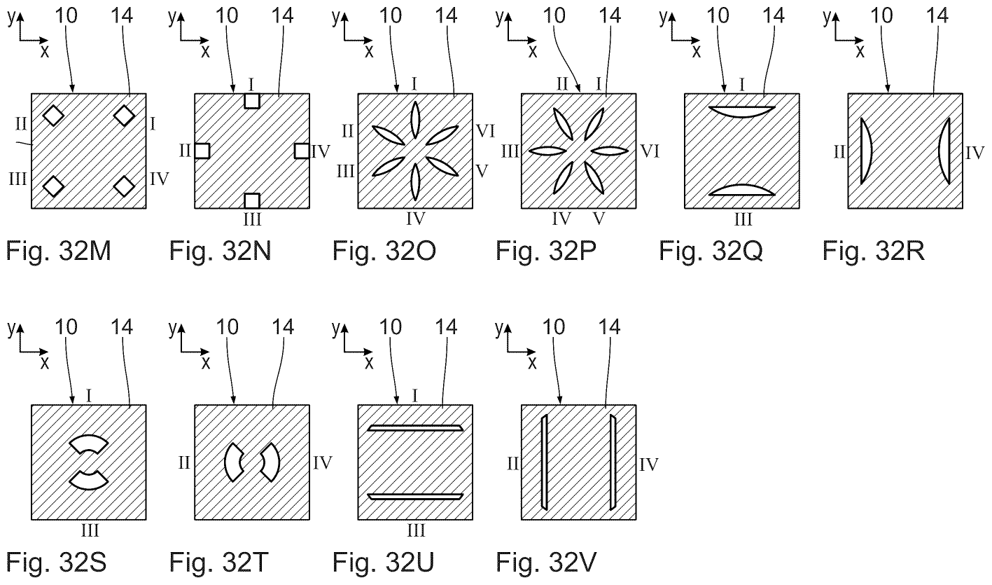

FIG. 32 elucidates further examples of illumination settings A to V of the optical production system to be simulated, once again represented in each case by an intensity distribution over an illumination pupil in an optical production system pupil plane. These are rendered representations of basic shapes of standardized illumination settings.

FIG. 32A shows an annular production illumination setting with the largest possible illumination angle. The production illumination setting according to FIG. 32A can be approximated using the measurement illumination pupil according to FIG. 3D.

FIG. 32B shows an annular production illumination setting with the smallest possible illumination angles around a central obscuration of the optical production system. The production illumination setting according to FIG. 32B can be approximated using the measurement illumination setting corresponding to the pupil according to FIG. 3A.

FIG. 32C shows a production illumination setting in the form of a y-dipole. This setting can be approximated using a measurement illumination setting corresponding to FIG. 5D.

FIG. 32D shows a production illumination setting in the form of an x-dipole, which in turn can be approximated using the measurement illumination setting according to FIG. 5C.

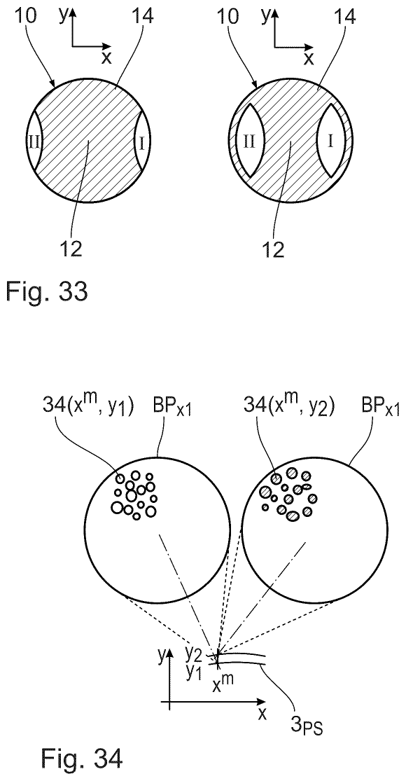

FIG. 33 shows a comparison of these two x-dipole settings. The production illumination setting corresponding to FIG. 32D is depicted to the left and the measurement illumination setting corresponding to FIG. 5C is depicted to the right. Assuming normalized pupil areas of the measurement illumination setting on the one hand and of the production illumination setting on the other hand, the measurement illumination setting has significantly larger pole regions to which intensity can be applied in comparison with the production illumination setting, i.e. it has overall a higher pupil filling degree than the production illumination setting. A pupil filling degree of the measurement illumination setting according to FIG. 33, right, may be of the order of 25%. A production pupil filling degree of the production illumination setting according to FIG. 33, left, is of the order of 10%. Thus, in the example according to FIG. 33, an illuminated pupil area of the measurement illumination setting is approximately 2.5 times as large as the illuminated pupil area of the production illumination setting.

FIG. 32E shows a production illumination setting in the form of a quadrupole illumination setting, which can be approximated using the measurement illumination setting according to FIG. 7A.

FIG. 32F shows a production illumination setting, once again in the form of a quadrupole illumination setting, which can be approximated using the measurement illumination setting according to FIG. 7B.

FIGS. 32G and 32H show further production illumination settings in the form of quadrupole illumination settings, which can be approximated using the measurement illumination settings corresponding to FIGS. 7D and 7C.

FIG. 32I shows a production illumination setting in the form of a further dipole setting with two leaflet illumination poles which, in a manner corresponding to the poles of the settings according to FIGS. 32G and 32H, extend tangentially to a pupil center and are arranged in quadrants II and IV. By selecting poles II and IV, for example, in the measurement illumination setting according to FIG. 7C, this production illumination setting according to FIG. 32I can be approximated by a corresponding measurement illumination setting.

FIG. 32J shows a further production illumination setting, once again in the form of a dipole illumination setting with illumination poles oriented in a manner corresponding to the setting according to FIG. 32I but arranged in quadrants I and III in this case. This production illumination setting according to FIG. 32J can be approximated by the measurement illumination setting according to FIG. 7C with illumination poles I and III selected in that case.

FIGS. 32K and 32L show two production illumination settings, each in the form of a hexapole setting, which can be approximated by use of the measurement illumination settings according to FIGS. 8D and 9D.

FIGS. 32M and 32N show two further production illumination settings in the form of quadrupole settings, which can be approximated by way of the measurement illumination settings according to FIGS. 6C and 6D.

FIGS. 32O and 32P show two further production illumination settings in the form of hexapole illumination settings, which can be approximated by way of the measurement illumination settings according to FIGS. 8C and 9C.

FIGS. 32Q and 32R show two further production illumination settings in the form of a y-dipole (FIG. 32Q) and an x-dipole (FIG. 32R) with different illumination pole shapes in comparison with the production illumination settings 32C and 32D. The illumination poles of the production illumination settings according to FIGS. 32Q and 32R each have the shape of circular segments, the respective convex curvature portion of which faces a pupil center. As a result of appropriate pole shaping in the measurement illumination settings according to FIGS. 5D and 5C, an approximation to the production illumination settings 32Q and 32R using measurement illumination settings is also possible in this case.

FIGS. 32S and 32T show two further production illumination settings in the form of dipole settings, which can be approximated by use of the measurement illumination settings according to FIGS. 5B (y-dipole) and 5A (x-dipole).

FIGS. 32U and 32V show two further variants of production illumination settings in the form of dipole settings, which can be approximated by use of the measurement illumination settings according to FIGS. 4D and 4C.

In a representation similar to FIG. 23, FIG. 34 shows a variation of an illumination pupil BP for two different field coordinates y₁, y₂ in the optical production system once again, using the example of a projection exposure apparatus designed as a scanner and having an object displacement direction y. Portions of two illumination pupils BPy₁ and BPy₂ of the illumination system of the optical production system in the style of the illumination setting of FIG. 10 are depicted once again with an exaggeratedly large dependence.

In FIG. 34, bottom, y₁ and y₂ denote two different field points along the same field height x^{m} of the projection field 3_{PS} of the optical production system, i.e. of the EUV reticle illumination field. The two illumination pupils BPy₁, BPy₂ specify the respective illumination angle distribution present during the object illumination of an object point, at the location of the coordinate y₁ at a first scanning time and then at the location of the coordinate y₂ in the object displacement direction at a further scanning time.

The illumination pupils BPy₁, BPy₂ once again differ in terms of the respective extent, in terms of the respective arrangement and in terms of the respective intensity distribution of the intensity spots 34. This is emphasized using the example of an illumination or intensity spot 34 (x^{m}, y) that is emphasized in FIG. 34 by use of a reference line. This illumination spot 34 has a comparatively small extent (cf. 34 (x^{m}, y₁)) at the object displacement coordinate y₁, whereas it has become significantly larger in terms of its extent relative thereto (cf. 34 (x^{m}, y₂)) at the object displacement location y₂. A corresponding statement applies to the other intensity spots 34 depicted in FIG. 34 in exemplary fashion.

Each of the intensity spots 34 of the respective EUV illumination pupil BP_{yi} varies in terms of its pupil coordinate position of a ρₓ, ρ_{y}, varies in terms of its intensity I and, in general, also in terms of its shape and polarization in a manner dependent on the object displacement coordinate yᵢ.

The reconstruction of the simulation method includes the fact that the optical production system to be simulated, as explained above in the context of FIG. 34, comprises a production illumination setting BP_{y} to be simulated, with the latter varying in the object displacement direction y.

To in particular simulate aberrations of the optical production system that are dependent on the object displacement coordinate y, i.e. for example to emulate aberrations in the scanning direction y, a corresponding y-dependence may be taken into account in the term P(\vec{k}, z_{target}) in Equation (4) above, and so P(k, z_{target}, x^{m}, t) depends not only on defocus z_{target}, but also on the field position x^{m} and the scanning time t and hence on the object displacement coordinate y

(y=v_{scan}·t with the object displacement or scanning speed v_{scan}):

$$P ( k , {z}_{target} , {x}^{m} , t ) = NA ( k ) {e}^{t \frac{2 π}{λ}} {z}_{target} \sqrt{1 - {\vert k \vert}^{2}} + iW ( k , {x}^{m} , t ) \qquad ( 18 )$$

In this case, W(x^{m}, t) denotes the wavefront aberration of the scanner at the field position x^{m} and at the scanning time t.

To record the aerial images Iₘₑₐₛ, use can be made of the measurement pupil stop 10 with a pupil filling degree that is significantly larger than the pupil filling degree of a production illumination setting to be simulated corresponding thereto.

In this case, the pupil filling degree is an area of an illuminated portion of a respective pupil in relation to an overall area of the pupil. An illuminated pupil area of the resultant measurement illumination setting may be at least 5% greater than the illuminated pupil area of the production illumination setting to be simulated. As already explained on the basis of FIG. 33, the ratio between the pupil filling degree of the measurement illumination setting and the pupil filling degree of the production illumination setting may also be very much larger; for example, it may be up to 250% and may be even greater still.

In a manner analogous to the above-described individual or separate optimization of pupil stops for the respective field point xⁱ, there can be a corresponding separate optimization of measurement pupil stops 10 for different coordinates yᵢ in the object displacement direction y as well. For example, two or three measurement pupil stops 10 that are optimized along the entire y-object displacement path through the object field 3 may be fabricated with the aid of the optimization rule explained above.

In a manner fitting to the object displacement point yᵢ to be measured in the object field 3, it is possible to use the corresponding stop or else a corresponding stop pair of pupil stop and aperture stop.

In a variant of the simulation method, it is also possible to use a plurality of different pupil stops 10 to specify the various measurement positions (kₓ, k_{y}).

To prepare the simulation method, it is possible to record an aerial image stack in order to make sure which z-pose of the object plane 4 supplies an optimally sharp image in the image plane 29 (zero of the z-pose).

z-increments which are used in Equation (2) when determining the aerial image Iₛᵢₘ may differ from the defocus values zₘ that are specified within the scope of the simulation method.

Pixel sizes of the recorded measurement aerial images Iₘₑₐₛ may be sampled for the purpose of matching to a desired pixel resolution.

A plurality of kₓ, k_{y} positions of the imaging pupil stop 23 can also be set by way of the displacement drive 25 in a simulation method.

When reconstructing the mask transfer function, it is accordingly possible to take account of imaging aberrations of the optical measurement system, in particular imaging aberrations of the imaging optics unit 20 of the metrology system 2.

The determination of the 3-D aerial image Iₘₑₐₛ and/or the calculation of the simulated aerial image Iₛᵢₘ may be carried out using a different illumination chief ray angle to that of the reconstruction of the mask transfer function.

For selecting the respective pupil stop 10 from the provided plurality of pupil stops 10 with in each case different stop boundary shapes and/or stop boundary orientations, the metrology system 2 has a selection apparatus not depicted in detail in the drawing. This selection apparatus has a stop storage unit, in which the plurality of pupil stops 10 with different stop boundary shapes and/or stop boundary orientations are stored in each case for the purpose of specifying correspondingly different measurement illumination settings.

In the selection step of the simulation method, the last pupil stop inserted is firstly removed from its use location in the pupil plane 11 and supplied to the stop storage unit in the selection apparatus with the aid of an actuator system of the selection apparatus, in particular with the aid of a robotic actuator system. Subsequently, the pupil stop 10 selected according to the simulation method is selected from the stop storage unit and inserted in the use position in the pupil plane 11 with the aid of the robotic actuator system. For example, the robotic actuator system can include a robotic arm (powered by motors) that retrieves a pupil stop 10 from the stop storage unit and places the pupil stop 10 in the illumination optics unit pupil plane 11, or retrieves the pupil stop 10 from the illumination optics unit pupil plane 11 and returns the pupil stop 10 in the stop storage unit.

In principle, the problem presented above and also the solution can be applied analogously to take account of machine-individual properties in the aerial image emulation. For instance, the EUV illumination pupils differ from machine to machine, depending on the light source used, in particular the EUV light source used. In particular, the combination of a stop emulating the ideal system and the simulation-type method incorporating the machine-individual component is attractive.

For instance, this requires that the machine-individual properties are known, for example by way of a qualification or, in the case of the EUV source types, by way of the appropriate numerical models. Machine-individual portions of the metrology system 2 can also be considered in similar fashion.

In general, the above-described approaches allow specific properties of the optical production system to be simulated, for example crosstalk effects between different illumination channels of a fly's eye integrator system in the illumination optics unit of the optical production component and/or crosstalk effects between various x-coordinate-dependent intensity correction stops in the illumination optics unit of the optical production system. For instance, it is possible to simulate insertion depths of appropriate stop fingers which correct the illumination intensity in x-coordinate-dependent fashion, and the influence thereof on the aerial image.

In some implementations, the processing of data, such as simulation of the illumination and imaging properties of the optical production system, can be carried out by one or more computers executing one or more computer programs each having code that implements one or more algorithms described above. Each computer can have one or more data processors. Each data processor can include one or more processor cores, and each processor core can include logic circuitry for processing data. For example, a data processor can include an arithmetic and logic unit (ALU), a control unit, and various registers. Each data processor can include cache memory. Each data processor can include a system-on-chip (SoC) that includes multiple processor cores, random access memory, graphics processing units, one or more controllers, and one or more communication modules. Each data processor can include millions or billions of transistors.

In some implementations, the computer program can be stored in one or more machine-readable storage devices, such as hard drives, magnetic disks, solid state drives, magneto-optical disks, or optical disks. Alternatively or in addition, the computer program can be encoded on a propagated signal that is an artificially generated signal, e.g., a machine-generated electrical, optical, or electromagnetic signal, that is generated to encode information for transmission to suitable receiver apparatus for execution by a programmable processor. The computer program can be written in any form of programming language, including compiled or interpreted languages, and it can be deployed in any form, including as a stand-alone program or as a module, component, subroutine, or other unit suitable for use in a computing environment.

In some implementations, the processes described above can be implemented using software for execution on one or more mobile computing devices, one or more local computing devices, and/or one or more remote computing devices (which can be, e.g., cloud computing devices). For instance, the software forms procedures in one or more computer programs that execute on one or more programmed or programmable computer systems, either in the mobile computing devices, local computing devices, or remote computing systems (which may be of various architectures such as distributed, client/server, grid, or cloud), each including at least one data processor, at least one data storage system (including volatile and non-volatile memory and/or storage elements), at least one wired or wireless input device or port, and at least one wired or wireless output device or port.

Although the present invention is defined in the attached claims, it should be understood that the present invention can also be defined in accordance with the following embodiments:

Embodiment 1: Method for simulating illumination and imaging properties of an optical production system when an object (5) is illuminated and imaged, wherein the simulation is implemented by an optical measurement system of a metrology system (2),
wherein the optical measurement system comprises an illumination optics unit (9) for illuminating the object (5) with a pupil stop (10) that is arranged in the region of an illumination pupil in a pupil plane (11) of the illumination optics unit (9),
wherein the simulation of the illumination and imaging properties of the optical production system includes a variation of a production illumination setting (BPy₁, BPy₂), to be simulated, such variation depending on an object displacement direction (y) of the object (5) along which the object (5) is displaced during production operation of the optical production system.

Embodiment 2: Method according to Embodiment 1, wherein the optical measurement system comprises an imaging optics unit (20) for imaging the object (5) into an image plane (29) and wherein the object (5) is displaceable perpendicular to an object plane (4), the method including the following steps:
providing at least one pupil stop (10) for specifying at least one measurement illumination setting created by the pupil stop (10),
recording measurement aerial images Iₘₑₐₛ in the image plane (29) for various displacement positions of the object (5) perpendicular to the object plane (4) with the at least one measurement illumination setting,
reconstructing a complex mask transfer function M from the recorded measurement aerial images Iₘₑₐₛ,
determining a 3-D aerial image Iₛᵢₘ of the optical production system from the reconstructed mask transfer function M and a specified illumination setting σ_{target} of the optical production system as the result of the simulation method,
wherein the reconstruction includes, as part of the simulation, the fact that the optical production system to be simulated comprises the production illumination setting (BPy₁, BPy₂) to be simulated, with the latter varying in the object displacement direction (y).

Embodiment 3: Method according to Embodiment 1 or 2, characterized in that the simulation includes the fact that the production illumination setting (BPy₁, BPy₂) varies in terms of its illumination intensity (I) in the object displacement direction (y) and/or in that the simulation includes the fact that the production illumination setting (BPy₁, BPy₂) varies in terms of its illumination angle distribution (ρₓ, ρ_{y}) in the object displacement direction (y).

Embodiment 4: Method for simulating illumination and imaging properties of an optical production system when an object (5) is illuminated and imaged, wherein the simulation is implemented by an optical measurement system of a metrology system (2),
wherein the optical measurement system comprises
   an illumination optics unit (9) for illuminating the object (5) with a pupil stop (10) that is arranged in the region of an illumination pupil in a pupil plane (11) of the illumination optics unit (9) and
   an imaging optics unit (20) for imaging the object (5) into an image plane (29),
wherein the object (5) is displaceable perpendicular to an object plane (4), including the following steps:
providing at least one pupil stop (10) for specifying at least one measurement illumination setting created by the pupil stop (10),
recording measurement aerial images Iₘₑₐₛ in the image plane (29) for various displacement positions of the object (5) perpendicular to the object plane (4) with the at least one measurement illumination setting,
reconstructing a complex mask transfer function M from the recorded measurement aerial images Iₘₑₐₛ,
determining a 3-D aerial image Iₛᵢₘ of the optical production system from the reconstructed mask transfer function M and a specified illumination setting σ_{target} of the optical production system as the result of the simulation method,
wherein the measurement illumination setting used when recording the measurement aerial images Iₘₑₐₛ has a measurement pupil filling degree that is greater than a production pupil filling degree of a production illumination setting to be simulated of the optical production system to be simulated.

Embodiment 5: Method according to Embodiment 4, characterized in that an illuminated pupil area of the measurement illumination setting is at least 1.25 times an illuminated pupil area of the production illumination setting to be simulated.

Embodiment 6: Method according to any of Embodiments 1 to 5, characterized in that at least one of the following correction terms is included when the mask transfer function M is reconstructed:
a calculated aerial image (I_{sim(\vec{r},z,x}_{^{m}}₎) for the associated defocus value and an associated field height, created by simulating an image by use of the imaging optics unit of the optical production system with the inclusion of reconstructed spectra of the object (5), and/or
a calculated aerial image (I_{sim(\vec{r},z,\vec{q})}) for the associated defocus value, created by simulating an image by use of the measurement imaging optics unit (20) with the inclusion of the reconstructed spectra.

Embodiment 7: Method according to any of Embodiments 1 to 6, characterized in that the recording of the measurement aerial images utilizes a pupil stop (10) whose stop shape is optimized with the aid of the following method steps:
specifying (45) a starting stop shape (10^{dc}) of the pupil stop (10) as an initial design candidate for the simulation,
modifying (46) the starting stop shape (10^{dc}) to give rise to a modification stop shape (10^{dcnew}) which is different from the most recently specified stop shape (10^{dc}),
checking (48) at least one fabrication boundary condition with regard to fabrication of the modification stop shape (10^{dcnew}) and repeating the “modifying” and “checking” steps until the checking (48) reveals compliance with the fabrication boundary condition,
ascertaining (49) a match quality between the illumination and imaging properties of the optical production system and the illumination and imaging properties of the optical measurement system as soon as the fabrication boundary conditions are complied with,
repeating the “modifying”, “checking” and “ascertaining” steps until the match quality attains a specified optimization criterion, which is checked by way of a query step (50),
fabricating (52) a target stop shape resulting from the attaining of the optimization criterion as an optimized pupil stop shape (39) after attaining the optimization criterion.

Embodiment 8: Method according to Embodiment 7, characterized in that the stop boundary (39) is optimized separately for a plurality of displacement positions (y₁, y₂) in the object displacement direction (y), with the result that this gives rise to a plurality of pupil stops (10) which can each be used for simulating the properties of the optical production system in the corresponding field region.

Embodiment 9: Metrology system (2) for carrying out a method according to any of claims 1 to 8,
wherein the optical measurement system comprises an illumination optics unit (9) serving to illuminate the object (5) and having a pupil stop (10) in the region of an illumination pupil in a pupil plane (11), and an imaging optics unit (20) for imaging the object (5) into the image plane (29).

Embodiment 10: Metrology system according to claim 9,
wherein the optical measurement system comprises a displacement drive (16) for displacing the pupil stop (10) in at least one displacement direction in the pupil plane (11),
wherein the optical measurement system comprises an object holder (17) which is displaceable perpendicular to an object plane (4) by actuator.

Embodiment 11: Metrology system according to Embodiment 9 or 10, characterized in that the optical measurement system comprises a displacement drive (25) for displacing, in at least one displacement direction in a pupil plane (22) of the imaging optics unit (20), an imaging pupil stop (23) arranged in the region of a pupil of the imaging optics unit (20).

Embodiment 12: Metrology system according to any of Embodiments 9 to 11, characterized by a selection apparatus for selecting at least one pupil stop from a plurality of pupil stops, wherein the selection apparatus comprises a stop storage unit with a plurality of pupil stops (10), each with different stop boundary shapes and/or stop boundary orientations for specifying correspondingly different measurement illumination settings.

A number of implementations have been described. Nevertheless, it will be understood that various modifications may be made. For example, the elements of one or more implementations may be combined, deleted, modified, or supplemented to form further implementations. In addition, other components may be added to, or removed from, the described metrology system. Accordingly, other implementations are within the scope of the following claims.

What is claimed is:

1. A method for simulating illumination and imaging properties of an optical production system when an object is illuminated and imaged, wherein the simulation is implemented by an optical measurement system of a metrology system,
wherein the optical measurement system comprises an illumination optics unit for illuminating the object with a pupil stop that is arranged in the region of an illumination pupil in a pupil plane of the illumination optics unit,
wherein the simulation of the illumination and imaging properties of the optical production system includes a variation of a production illumination setting, to be simulated, such variation depending on an object displacement direction of the object along which the object is displaced during production operation of the optical production system.

2. The method according to claim 1, wherein the optical measurement system comprises an imaging optics unit for imaging the object into an image plane and wherein the object is displaceable perpendicular to an object plane, the method including the following steps:
providing at least one pupil stop for specifying at least one measurement illumination setting created by use of the pupil stop,
recording measurement aerial images in the image plane for various displacement positions of the object perpendicular to the object plane with the at least one measurement illumination setting,
reconstructing a complex mask transfer function from the recorded measurement aerial images, and
determining a 3-D aerial image of the optical production system from the reconstructed mask transfer function and a specified illumination setting of the optical production system as the result of the simulation method,
wherein the reconstruction includes, as part of the simulation, the fact that the optical production system to be simulated comprises the production illumination setting to be simulated, with the latter varying in the object displacement direction.

3. The method according to claim 1, wherein the simulation includes the fact that the production illumination setting varies in terms of its illumination intensity in the object displacement direction and/or in that the simulation includes the fact that the production illumination setting varies in terms of its illumination angle distribution in the object displacement direction.

4. A method for simulating illumination and imaging properties of an optical production system when an object is illuminated and imaged, wherein the simulation is implemented by use of an optical measurement system of a metrology system,
wherein the optical measurement system comprises
an illumination optics unit for illuminating the object with a pupil stop that is arranged in the region of an illumination pupil in a pupil plane of the illumination optics unit and
an imaging optics unit for imaging the object into an image plane,
wherein the object is displaceable perpendicular to an object plane, including the following steps:
providing at least one pupil stop for specifying at least one measurement illumination setting created by use of the pupil stop,
recording measurement aerial images in the image plane for various displacement positions of the object perpendicular to the object plane with the at least one measurement illumination setting,
reconstructing a complex mask transfer function from the recorded measurement aerial images,
determining a 3-D aerial image of the optical production system from the reconstructed mask transfer function and a specified illumination setting of the optical production system as the result of the simulation method,
wherein the measurement illumination setting used when recording the measurement aerial images has a measurement pupil filling degree that is greater than a production pupil filling degree of a production illumination setting to be simulated of the optical production system to be simulated.

5. The method according to claim 4, wherein an illuminated pupil area of the measurement illumination setting is at least 1.25 times an illuminated pupil area of the production illumination setting to be simulated.

6. The method according to claim 1, wherein at least one of the following correction terms is included when the mask transfer function is reconstructed:
a calculated aerial image for the associated defocus value and an associated field height, created by simulating an image by use of the imaging optics unit of the optical production system with the inclusion of reconstructed spectra of the object, and/or
a calculated aerial image for the associated defocus value, created by simulating an image by use of the measurement imaging optics unit with the inclusion of the reconstructed spectra.

7. The method according to claim 1, wherein the recording of the measurement aerial images utilizes a pupil stop whose stop shape is optimized with the aid of the following method steps:
specifying a starting stop shape of the pupil stop as an initial design candidate for the simulation,
modifying the starting stop shape to give rise to a modification stop shape which is different from the most recently specified stop shape,
checking at least one fabrication boundary condition with regard to fabrication of the modification stop shape and repeating the “modifying” and “checking” steps until the checking reveals compliance with the fabrication boundary condition,
ascertaining a match quality between the illumination and imaging properties of the optical production system and the illumination and imaging properties of the optical measurement system as soon as the fabrication boundary conditions are complied with,
repeating the “modifying”, “checking” and “ascertaining” steps until the match quality attains a specified optimization criterion, which is checked by way of a query step, and
fabricating a target stop shape resulting from the attaining of the optimization criterion as an optimized pupil stop shape after attaining the optimization criterion.

8. The method according to claim 7, wherein the stop boundary is optimized separately for a plurality of displacement positions in the object displacement direction, with the result that this gives rise to a plurality of pupil stops which can each be used for simulating the properties of the optical production system in the corresponding field region.

9. A metrology system for carrying out a method for simulating illumination and imaging properties of an optical production system when an object is illuminated and imaged, wherein the simulation is implemented by an optical measurement system of a metrology system,
wherein the optical measurement system comprises an illumination optics unit serving to illuminate the object and having a pupil stop in the region of an illumination pupil in a pupil plane of the illumination optics unit, and an imaging optics unit for imaging the object into the image plane,
wherein the simulation of the illumination and imaging properties of the optical production system includes a variation of a production illumination setting, to be simulated, such variation depending on an object displacement direction of the object along which the object is displaced during production operation of the optical production system.

10. The metrology system according to claim 9,
wherein the optical measurement system comprises a displacement drive for displacing the pupil stop in at least one displacement direction in the pupil plane,
wherein the optical measurement system comprises an object holder which is displaceable perpendicular to an object plane by actuator.

11. The metrology system according to claim 9, wherein the optical measurement system comprises a displacement drive for displacing, in at least one displacement direction in a pupil plane of the imaging optics unit, an imaging pupil stop arranged in the region of a pupil of the imaging optics unit.

12. The metrology system according to claim 9, comprising a selection apparatus for selecting at least one pupil stop from a plurality of pupil stops, wherein the selection apparatus comprises a stop storage unit with a plurality of pupil stops, each with different stop boundary shapes and/or stop boundary orientations for specifying correspondingly different measurement illumination settings.

13. The metrology system of claim 10 wherein the optical measurement system comprises a displacement drive for displacing, in at least one displacement direction in a pupil plane of the imaging optics unit, an imaging pupil stop arranged in the region of a pupil of the imaging optics unit.

14. The metrology system of claim 10, comprising a selection apparatus for selecting at least one pupil stop from a plurality of pupil stops, wherein the selection apparatus comprises a stop storage unit with a plurality of pupil stops, each with different stop boundary shapes and/or stop boundary orientations for specifying correspondingly different measurement illumination settings.

15. The method of claim 4 wherein at least one of the following correction terms is included when the mask transfer function is reconstructed:
a calculated aerial image for the associated defocus value and an associated field height, created by simulating an image by use of the imaging optics unit of the optical production system with the inclusion of reconstructed spectra of the object, or
a calculated aerial image for the associated defocus value, generated by simulating an image by use of the measurement imaging optics unit with the inclusion of the reconstructed spectra.

16. The method of claim 4 wherein the recording of the measurement aerial images utilizes a pupil stop whose stop shape is optimized with the aid of the following method steps:
specifying a starting stop shape of the pupil stop as an initial design candidate for the simulation,
modifying the starting stop shape to give rise to a modification stop shape which is different from the most recently specified stop shape,
checking at least one fabrication boundary condition with regard to fabrication of the modification stop shape and repeating the “modifying” and “checking” steps until the checking reveals compliance with the fabrication boundary condition,
ascertaining a match quality between the illumination and imaging properties of the optical production system and the illumination and imaging properties of the optical measurement system as soon as the fabrication boundary conditions are complied with,
repeating the “modifying”, “checking” and “ascertaining” steps until the match quality attains a specified optimization criterion, which is checked by way of a query step, and
fabricating a target stop shape resulting from the attaining of the optimization criterion as an optimized pupil stop shape after attaining the optimization criterion.

17. The method of claim 16 wherein the stop boundary is optimized separately for a plurality of displacement positions in the object displacement direction, with the result that this gives rise to a plurality of pupil stops which can each be used for simulating the properties of the optical production system in the corresponding field region.

18. The metrology system of claim 9 wherein the optical measurement system comprises an imaging optics unit for imaging the object into an image plane and wherein the object is displaceable perpendicular to an object plane, the method including the following steps:
providing at least one pupil stop for specifying at least one measurement illumination setting created by use of the pupil stop,
recording measurement aerial images in the image plane for various displacement positions of the object perpendicular to the object plane with the at least one measurement illumination setting,
reconstructing a complex mask transfer function from the recorded measurement aerial images, and
determining a 3-D aerial image of the optical production system from the reconstructed mask transfer function and a specified illumination setting of the optical production system as the result of the simulation method,
wherein the reconstruction includes, as part of the simulation, the fact that the optical production system to be simulated comprises the production illumination setting to be simulated, with the latter varying in the object displacement direction.

19. The metrology system of claim 9 wherein the simulation includes the fact that the production illumination setting varies in terms of its illumination intensity in the object displacement direction and/or in that the simulation includes the fact that the production illumination setting varies in terms of its illumination angle distribution in the object displacement direction.

20. The metrology system of claim 9 wherein at least one of the following correction terms is included when the mask transfer function is reconstructed:
a calculated aerial image for the associated defocus value and an associated field height, created by simulating an image by use of the imaging optics unit of the optical production system with the inclusion of reconstructed spectra of the object, and/or
a calculated aerial image for the associated defocus value, created by simulating an image by use of the measurement imaging optics unit with the inclusion of the reconstructed spectra.
